(19) United States
(12) Patent Application Publication
(10) Pub. No.: US 2024/0389483 A1
(43) Pub. Date: Nov. 21, 2024

(54) PHASE CHANGE MATERIAL SWITCH INCLUDING AN IONIC RESISTANCE CHANGE MATERIAL HEATING ELEMENT AND METHODS FOR FORMING THE SAME

(71) Applicant: Taiwan Semiconductor Manufacturing Company Limited, Hsinchu (TW)

(72) Inventors: Yu-Wei Ting, Taipei City (TW); Harry-Hak-Lay Chuang, Zhubei city (TW); Kuo-Pin Chang, Zhubei city (TW); Kuo-Ching Huang, Hsinchu City (TW)

(21) Appl. No.: 18/317,118

(22) Filed: May 15, 2023

(51) Int. Cl. H10N 70/00; H10N 70/20

(52) U.S. Cl. CPC H10N 70/8413; H10N 70/023; H10N 70/026; H10N 70/231; H10N 70/8828

(57) ABSTRACT

An embodiment phase change material (PCM) switch may include a phase change material element, a first electrode, a second electrode, and a direct heating element including an ionic resistance change material contacting the phase change material element. The phase change material element may include a phase change material that switches from an electrically conducting phase to an electrically insulating phase or from an electrically insulating phase to an electrically conducting phase by application of a heat pulse generated by the heating element. The PCM switch may further include a switching electrode contacting the ionic resistance change material such that the ionic resistance change material may be switched from a high resistance to a low resistance state by application of voltages to the first electrode, the second electrode, and the switching electrode. Electrical currents within the ionic resistance change material may generate heat that switches the phase change material element.

### BACKGROUND

Electronic devices may utilize switches to route a signal along a transmission path. For example, a communication device (e.g., cell phone) may include many antenna elements and multiple radio streams to ensure high data rate wireless communications, whether through cellular or mobile connectivity networks and peripheral devices. The communication device may utilize radio frequency (RF) switches to route an RF signal along a transmission path that may include multiple RF components such as amplifiers, filters, etc. Phase change material (PCM) switches may be used for various applications such as RF applications. Advantages of PCM switches include their immunity to interference by electromagnetic radiation, relatively fast switching times, and ability to maintain their switching state (i.e., “On” or “Off”) without consuming electrical power.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of an RF transceiver system, according to various embodiments.

FIG. 2A is a schematic illustration of an antenna switch in a first configuration, according to various embodiments.

FIG. 2B is a schematic illustration of the antenna switch in a second configuration, according to various embodiments.

FIG. 3A is a top view of a PCM switch, according to various embodiments.

FIG. 3B is a vertical cross-sectional view of a portion of the PCM switch of FIG. 3A, according to various embodiments.

FIG. 3C is a vertical cross-sectional view of a further PCM switch, according to various embodiments.

FIG. 3D is a vertical cross-sectional view of a further PCM switch, according to various embodiments.

FIG. 3E is a vertical cross-sectional view of a further PCM switch, according to various embodiments.

FIG. 4A is a top view of a further PCM switch, according to various embodiments.

FIG. 4B is a vertical cross-sectional view of a portion of the PCM switch of FIG. 4A, according to various embodiments.

FIG. 4C is a vertical cross-sectional view of a further PCM switch, according to various embodiments.

FIG. 4D is a vertical cross-sectional view of a further PCM switch, according to various embodiments.

FIG. 4E is a vertical cross-sectional view of a further PCM switch, according to various embodiments.

FIG. 5A is a vertical cross-sectional view of a PCM switch that includes a direct heating mechanism provided by an ionic resistance change material, according to various embodiments.

FIG. 5B is a vertical cross-sectional view of a further PCM switch that includes a direct heating element provided by an ionic resistance change material, according to various embodiments.

FIG. 6A is a vertical cross-sectional view of an electrochemical cell including an ionic resistance change material in a first configuration, according to various embodiments.

FIG. 6B is a vertical cross-sectional view of the electrochemical cell including an ionic resistance change material in a second configuration, according to various embodiments.

FIG. 6C is a vertical cross-sectional view of the electrochemical cell including an ionic resistance change material in a third configuration, according to various embodiments.

FIG. 6D is a vertical cross-sectional view of the electrochemical cell including an ionic resistance change material in a fourth configuration, according to various embodiments.

FIG. 7 is a vertical cross-sectional view of a first exemplary structure after formation of complementary metal-oxide-semiconductor (CMOS) transistors, metal interconnect structures, and dielectric material layers, according to various embodiments.

FIG. 8A is a vertical cross-section view of an exemplary intermediate structure during a process of forming a PCM switch illustrating a trench formed in a first switch dielectric material layer, according to various embodiments.

FIG. 8B is a top view of the exemplary intermediate structure of FIG. 8A.

FIG. 9A is a vertical cross-section view of a further exemplary intermediate structure during a process of forming a PCM switch illustrating a heater pad embedded within the first switch dielectric material layer, according to various embodiments.

FIG. 9B is a top view of the exemplary intermediate structure of FIG. 9A.

FIG. 10 is a vertical cross-section view of a further exemplary intermediate structure during a process of forming a PCM switch showing a continuous phase change material (PCM) layer formed over the upper surface of a solid electrolyte layer, according to various embodiments.

FIG. 11A is a vertical cross-section view of a further exemplary intermediate structure during a process of forming a PCM switch illustrating a discrete PCM layer over the upper surface of the solid electrolyte layer, according to various embodiments.

FIG. 11B is a top view of the exemplary intermediate structure of FIG. 11A.

FIG. 12A is a vertical cross-section view of a further exemplary intermediate structure during a process of forming a PCM switch illustrating a continuous electrode layer formed over the intermediate structure of FIG. 11A, according to various embodiments.

FIG. 12B is a top view of the exemplary intermediate structure of FIG. 12A.

FIG. 13A is a vertical cross-section view of a PCM switch including a first electrode and a second electrode formed over the upper surface of the solid electrolyte layer and the upper surface and side surfaces of the PCM layer.

FIG. 13B is a top view of the PCM switch of FIG. 13A.

FIG. 14 is a top view of a PCM switch schematically illustrating a signal pathway across the PCM switch, according to various embodiments.

FIG. 15 is a flowchart illustrating operations of an embodiment method of fabricating a PCM switch, according to various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Elements with the same reference numerals refer to the same element and are presumed to have the same material composition and the same thickness range unless expressly indicated otherwise.

Various embodiment structures and methods are disclosed herein that may be used to form a PCM switch. Various embodiment PCM switches may be used to provide a switching function for various semiconductor devices such as radio-frequency semiconductor devices, varactors (i.e., variable capacitance capacitors), inductors, or other semiconductor devices. As used herein, a “phase change material” refers to a material having at least two distinct phases providing different resistivity. The distinct phases may include an amorphous state having relatively high resistivity and a crystalline state having relatively low resistivity (i.e., a lower resistivity than in the amorphous state). The transition between the amorphous state and the crystalline state may be induced by controlling a time-versus-temperature thermal profile within the phase change material. For example, a PCM switch may include a resistive heating element thermally coupled to the phase change material and configured to selectively heat the phase change material via the application of current pulses through the resistive heating element.

To induce a transition of the phase change material from a low-resistivity crystalline state to a high-resistivity amorphous state, the current pulse through the resistive heating element may have a relatively short pulse width with a short falling time that is configured to quickly heat the phase change material to a temperature above its melting temperature (Tₘₑₗₜ), causing the material to transition from an ordered crystalline low-resistivity phase to a disordered amorphous high-resistivity phase. The short falling time of the pulse may promote rapid quenching and may inhibit re-crystallization of the material as it cools.

To induce a transition of the phase change material from a high-resistivity amorphous state to a low-resistivity crystalline state, the current pulse through the resistive heating element may have a relatively longer pulse width with a longer pulse falling time that is configured to heat the phase change material to a temperature above its crystallization temperature (T_{crys}), but below its melting temperature (Tₘₑₗₜ), over a time period sufficient to induce crystal nucleation in the material. The comparatively longer falling time of the current pulse may promote crystal growth as the phase change material cools at a relatively slower rate.

A PCM switch may include a phase change material disposed within a signal transmission pathway between a pair of electrodes. The resistive heating element may extend across the phase change material in a direction transverse to the signal transmission pathway, and a layer of electrically-insulating and thermally-conductive material may be disposed between the resistive heating element and the phase change material. In other embodiments, the resistive heating element may be formed in direct contact with the phase change material. While the phase change material is in a low-resistivity crystalline state, the PCM switch may be in an “On” state (i.e., the switch is closed) such that signals may be transmitted across the phase change material between the pair of electrodes. However, when a portion of the phase change material along the signal transmission pathway is in a high-resistivity amorphous state, the PCM switch may be in an “Off” state (i.e., the switch is open) such that signal transmission between the pair of electrodes is blocked. The PCM switch may be switched (i.e., programmed) between the “On” state and the “Off” state by the selective application of current pulses to the resistive heating element having different pulse widths and falling times as described above. The portion of the phase change material that is switched between a low-resistivity crystalline state and a high-resistivity amorphous state may be referred to as the active region of the phase change material.

Radio-frequency switches are commonly found in, among other things, wireless communication devices. Such switches may be configured to facilitate coupling various circuits of a wireless communication device to an antenna. For example, it may be desirable to couple a first set of circuits to the antenna when receiving information through the antenna and to couple a second set of circuits to the antenna when transmitting information. As another example, it may be desirable to couple a first set of circuits to the antenna when communicating via a first communication scheme and to couple a second set of circuits to the antenna when communicating via a second communication scheme.

For a switch used in RF applications, relevant factors for evaluating switch performance may include insertion loss, isolation, and power handling. In general, low insertion loss and high isolation are desirable characteristics for RF switches. For PCM switches, insertion loss may be related to the resistivity R_{ON} across the phase change material when the switch is in the “On” state, while high isolation is inversely related to the capacitance C_{OFF} of the switch while in the “Off” state. A figure of merit (FOM) that may be used to characterize performance of a PCM switch may be chosen to have a value that is inversely proportional to the product R_{ON}*C_{OFF}. For example, one FOM that may be used to characterize switch performance may be taken to be ˜1/(2πR_{ON}*C_{OFF}). This FOM has frequency units and may be related to a maximum frequency at which the PCM material may be switched from an “On” state to an “Off” state. In general, increasing the value the FOM may be associated with improved switch performance. Thus, switch performance may be improved by reducing the R_{ON} characteristics, reducing the C_{OFF} characteristics, or both, in a PCM switch. The switching time of a PCM switch may also depend on a rate at which thermal energy may be diffused away from the PCM switch.

Disclosed embodiment PCM switches may be desired as they may include a direct heat source that does not lead to problems with material segregation. In this regard, an ionic resistance change material (i.e., a solid electrolyte) may be formed in direct contact with a phase change material element. In a low resistive state, the ionic resistance change material may form electrically conducting filaments within the ionic resistance change material that may support electrical currents having a relatively high current density that may act as local heat sources that produce heat through Ohmic loss. In this way, the embodiment PCM switches may exhibit relatively high efficiency of thermal energy transfer due to the close proximity (e.g., direct contact) of the heat sources to the phase change material element.

Further, the embodiment PCM switches may be less prone to segregation issues by incorporating a solid electrolyte, as the ionic resistance change material, which is compatible with the phase change material element (not subject to material segregation), thus leading to greater endurance relative to existing PCM switches having direct contact heat sources. In this regard, embodiment PCM switches may exhibit endurance (i.e., durability) that is comparable to or greater than that of existing PCM switches having indirect heat sources (and consequently requiring higher switching power). As such, the embodiment PCM switches may not be subject to tradeoffs between switching power and performance (i.e., endurance) that are characteristics of existing PCM switches.

An embodiment PCM switch may include a phase change material element, a first electrode, a second electrode, and a direct heating element including an ionic resistance change material contacting the phase change material element. The phase change material element may include a phase change material that switches from an electrically conducting phase to an electrically insulating phase or from an electrically insulating phase to an electrically conducting phase by application of a heat pulse generated by the heating element. The PCM switch may further include a switching electrode contacting the ionic resistance change material such that the ionic resistance change material may be switched from a high resistance to a low resistance state by application of voltages to the first electrode, the second electrode, and the switching electrode. Electrical currents within the ionic resistance change material may generate heat that switches the phase change material element.

A further embodiment PCM switch may include a phase change material element, a first electrical conductor coupled the phase change material element, a second electrical conductor coupled to the phase change material element, a direct heating element including an ionic resistance change material contacting the phase change material element and configured to supply a heat pulse to the phase change material element, and a switching electrode contacting the ionic resistance change material such that the ionic resistance change material is disposed between the phase change material element and the switching electrode. The first electrical conductor, the second electrical conductor, and the phase change material element may be configured to form an RF switch that is switchable from an electrically insulating phase that blocks RF signals to an electrically conducting phase that conducts RF signals.

An embodiment method of forming a PCM switch may include forming a switching electrode; forming an ionic resistance change material over the switching electrode and in contact with the switching electrode; forming a phase change material element over the ionic resistance change material and in contact with the ionic resistance change material; forming a first electrical conductor in contact with the phase change material element and the ionic resistance change material; and forming a second electrical conductor in contact with the phase change material element and the ionic resistance change material. The first electrical conductor, the second electrical conductor, and the phase change material element may be configured to form an RF switch that is switchable from an electrically insulating phase that blocks RF signals to an electrically conducting phase that conducts RF signals.

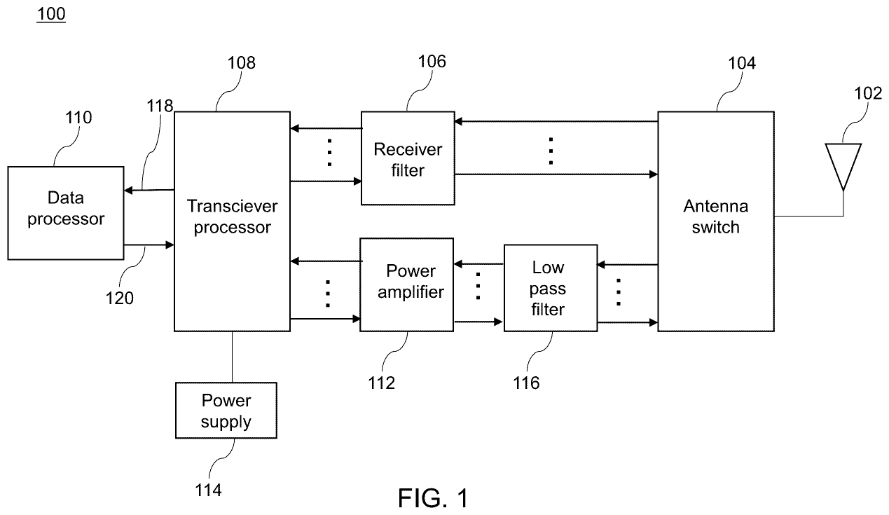

FIG. 1 is an exemplary block diagram of an RF transceiver system 100, according to various embodiments. The RF transceiver system 100 may include at least one antenna 102, an antenna switch 104, a receiver filter 106, a transceiver processor 108, a data processor 110, a power amplifier 112, a power supply 114, and a low pass filter 116. In some embodiments, the antenna switch 104 may be used to direct a signal from the antenna 102 to the receiver filter 106 or from the low pass filter 116 output to the antenna 102. The antenna switch may have low loss (e.g., <0.1 dB) to avoid adding to system noise or attenuating the transmit signal.

In some embodiments, the receiver filter 106 may be configured to filter signals to eliminate out-of-band signals so that such out-of-band signals may not be amplified or impact the linearity of the transceiver processor 108. In some embodiments, the transceiver processor 108 may further include at least one of a low noise amplifier, an RF filter, a mixer, a demodulator, a digital-to-analog converter, an analog-to-digital converter, and a modulator. First data 118, which may be received from the receiver filter 106 may be provided to a data processor 110. Similarly, second data 120, which is to be provided to the antenna 102 for transmission by the antenna 102, may be provided from the data processor 110 to the transceiver processor 108.

After being processed by the transceiver processor 108, the second data 120 may be amplified by the power amplifier 112 and may be filtered by the low pass filter 116 before being provided to the antenna switch 104. In turn, the antenna switch 104 may provide the second data 120, received from the low pass filter 116, to the antenna 102 for transmission. In the illustrated embodiment RF transceiver system 100, the antenna switch 104 may share one antenna 102 in transmission and reception and may be configured and controlled to switch the signal path. In some embodiments, the antenna switch 104 may be configured to exhibit low loss and low power consumption.

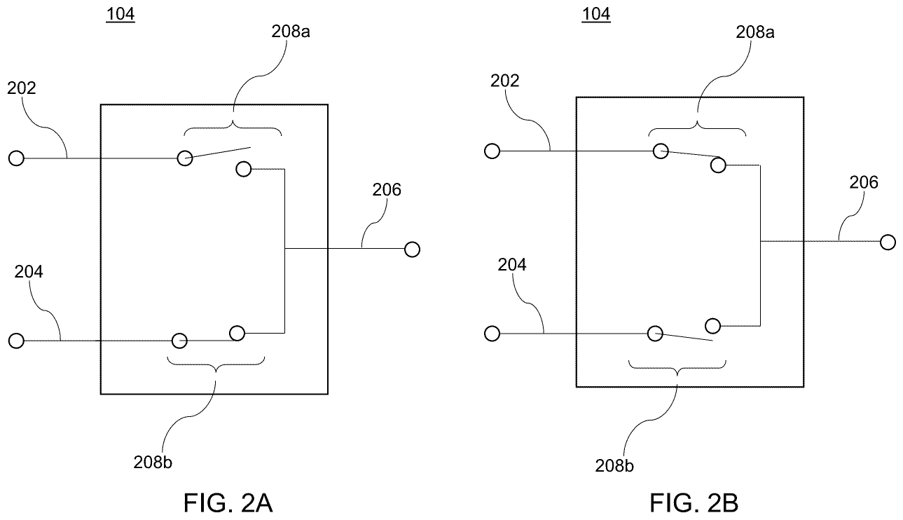

FIG. 2A is a schematic illustration of the antenna switch 104 in a first configuration, and FIG. 2B is a schematic illustration of the antenna switch 104 in a second configuration. The antenna switch 104 may include a receive node 202, a transmit node 204, and an antenna node 206. The antenna switch 104 may include a first RF switch 208a and a second RF switch 208b. As shown in FIG. 2A, in a first configuration, the first RF switch 208a may be open and the second RF switch 208b may be closed. As such, the antenna node 206 may be electrically connected to the transmit node 204. Alternatively, as shown in FIG. 2B, the first RF switch 208a may be closed and the second RF switch 208b may be open. As such, the antenna node 206 may be electrically connected to the receive node 202.

FIGS. 2A and 2B, suggest that the antenna switch 104 may be implemented using two RF switches (208a, 208b). Such RF switches (208a, 208b) may each be implemented using one or more transistors, resistors, inductors, capacitors, diodes, etc. For example, the antenna switch 104 may include various other circuit components such as a voltage controller. In various embodiments, various circuit components may include switching elements including one or more suitable electronic switches, such as insulated gate bipolar transistors (IGBTs), bipolar junction transistors (BJTs), field-effect transistors (FETs), metal-oxide semiconductor field-effect transistors (MOSFETs), gate turnoff thyristors (GTOs), integrated gate-commutated thyristors (IGCTs), bidirectional triode thyristors (TRIACs), etc. Various other embodiments may be implemented using high-performance PCM switch elements, as described in greater detail below.

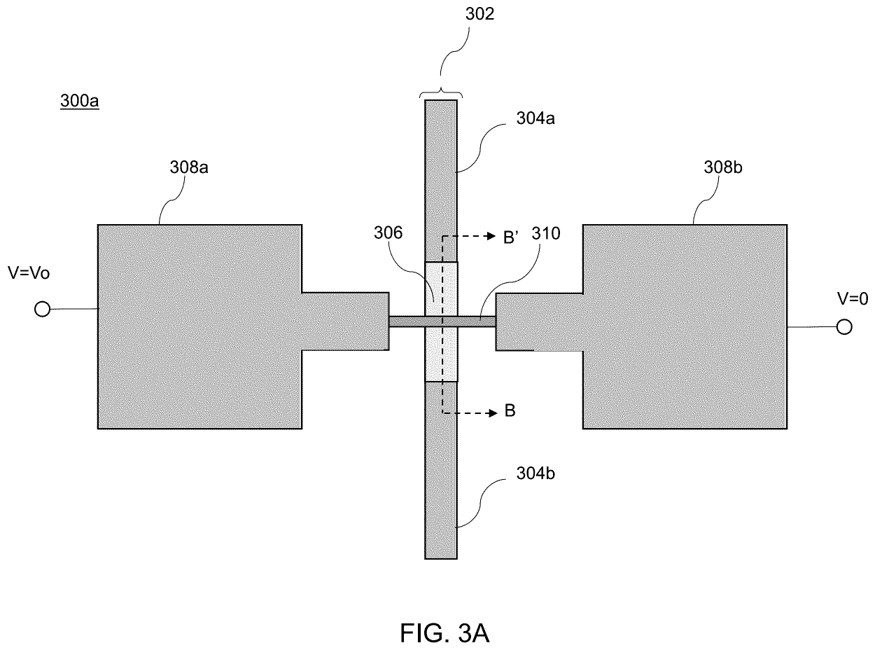

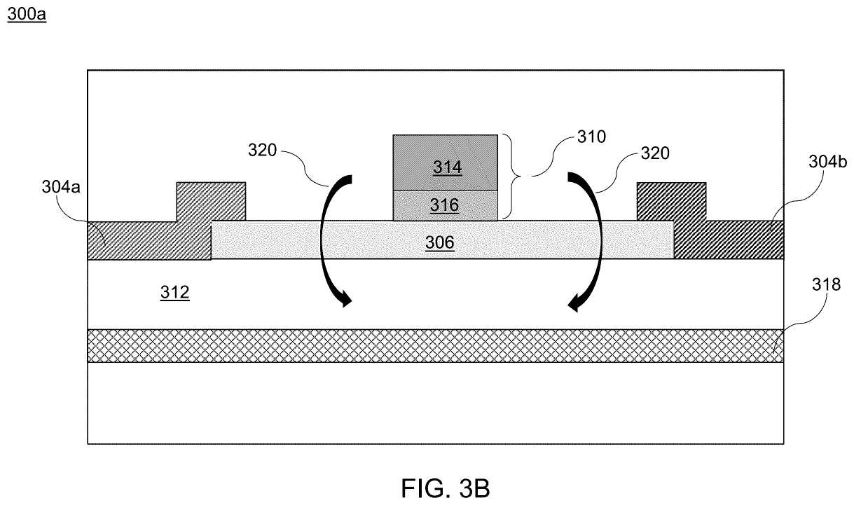

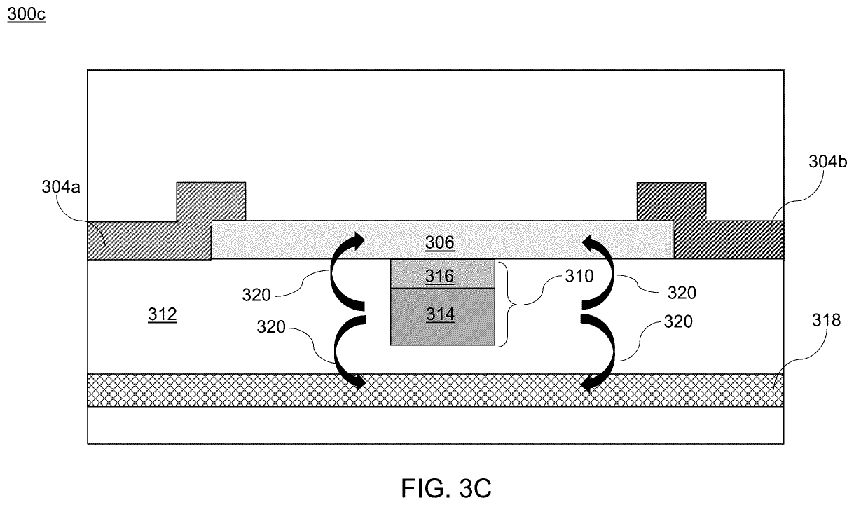

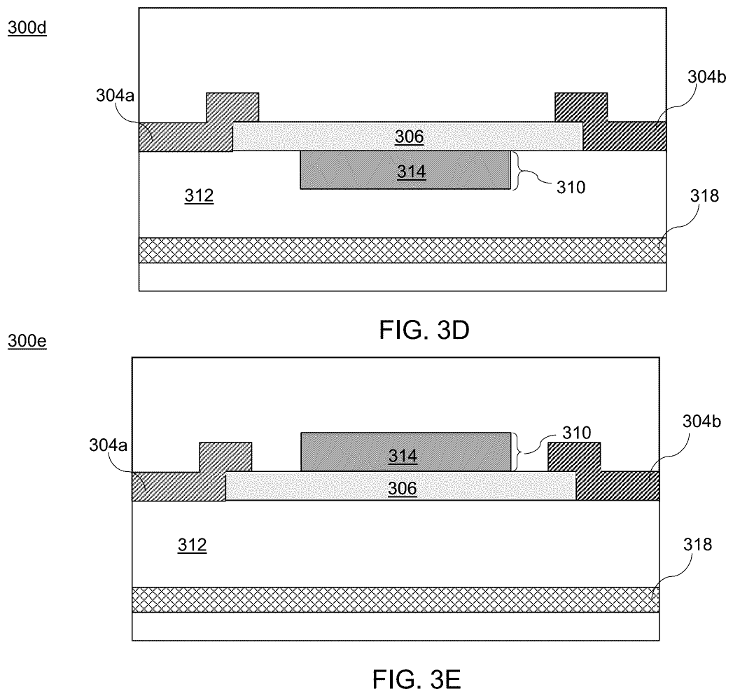

FIG. 3A is a top view of a PCM switch 300a, and FIG. 3B is a vertical cross-sectional view of a portion of the PCM switch 300a of FIG. 3A, according to various embodiments. The vertical cross-sectional plane that defines the view of FIG. 3B is indicated by the cross-section B-B′ in FIG. 3A. The PCM switch 300a may include an RF signal line 302 having a first electrical conductor 304a and a second electrical conductor 304b. The PCM switch 300a may further include a phase change material element 306 that may be in contact with the first electrical conductor 304a and the second electrical conductor 304b. As described above, the phase change material element 306 may be in a conducting state or in an insulating state. In instances in which the phase change material element 306 is in a conducting state, the PCM switch is closed (i.e., the switch is in an “On” state) and RF signals may propagate along the RF signal line 302 from the first electrical conductor 304a to the second electrical conductor 304b or from the second electrical conductor 304b to the first electrical conductor 304a. In instances in which the phase change material element 306 is in an insulating state, the PCM switch 300a is open (i.e., the switch is in an “Off state) and propagation of RF signals along the RF signal line 302 is prevented.

The PCM switch 300a may further include a first heater pad 308a and a second heater pad 308b. The first heater pad 308a and the second heater pad 308b may each be electrically connected to a heating element 310. The first heater pad 308a, the second heater pad 308b, and the heating element 310 may each be formed of a conducting material. In some embodiments, each of the first heater pad 308a, the second heater pad 308b, and the heating element 310, may be formed of the same conducting material. Alternatively, two or more different electrically conducting materials may be used for the first heater pad 308a, the second heater pad 308b, and the heating element 310.

Application of voltage difference between the first heater pad 308a (e.g., held at V=Vo) and the second heater pad 308b (e.g., held at V=0) may generate an electrical current that may flow from the first heater pad 308a, through the heating element 310, and to the second heater pad 308b, or from the second heater pad 308b, through the heating element 310, and to the first heater pad 308a, depending on the sign of the applied voltage Vo. The resistance of a given electrical circuit element (e.g., each of the first heater pad 308a, the second heater pad 308b, and the heating element 310) is proportional to a length along the direction of current flow and inversely proportional to a cross-sectional area perpendicular to current flow. As such, the first heater pad 308a and the second heater pad 308b may be configured to have a considerably larger width that that of the heating element 310. Therefore, for a given applied voltage difference, the current density may be considerably larger in the heating element 310 relative to that in either of the first heater pad 308a and the second heater pad 308b. As such, heat generated due to Ohmic loss will be produced at a greater rate (i.e., have a greater value of I²R power) in the heating element 310 in comparison with heat generated in the first heater pad 308a and the second heater pad 308b. In this way, heat may be preferentially generated by the heating element 310 and may be delivered to the phase change material element 306.

As shown in FIG. 3B, the PCM switch 300a may include a phase change material element 306 electrically connected to the first electrical conductor 304a and to the second electrical conductor 304b. Each of the first electrical conductor 304a, the second electrical conductor 304b, and the phase change material element 306 may be formed over a first switch dielectric material layer 312. As described in greater detail below, the heating element 310 may be formed above the phase change material element 306 such as to be in contact with a portion of the phase change material element 306. In this example embodiment, the heating element 310 may include a conductive heater pad 314 and a capping layer 316. Further, the capping layer 316 may be an electrically insulating material while being a heat conductor.

As shown in FIG. 3B, the PCM switch 300a may further include a heat spreader 318 formed below the phase change material element 306 on an opposite side of the phase change material element 306 from the heating element 310. The heat spreader 318 may be formed of a material having a high thermal conductivity. For example, the heat spreader 318 may have a planar slab geometry and may be a metal or a compound semiconductor (e.g., SiC) having a high thermal conductivity (e.g., >100 W/mK). The heat spreader 318 may be configured to remove heat from the phase change material element 306 during a cool-down phase after a switching event (e.g., switching from insulating to conducting or from conducting to insulating). As shown, the heat spreader 318 may be configured to cause heat to flow preferentially from the heating element 310, through the phase change material element 306, and toward the heat spreader 318, as indicated by the arrows 320 shown in FIG. 3B. Thus, the heating element 310 may be coupled to a first side (e.g., the top side) of the phase change material element 306 and the heat spreader 318 may be formed on a second side (e.g., the bottom side) of the phase change material element 306 opposite to the heating element 310. In other embodiments, however, the heat spreader 318 and the heating element 310 may be formed on the same side of the phase change material element 306 as described with reference to FIG. 3C, below.

FIG. 3C is a vertical cross-sectional view of a further PCM switch 300c, according to various embodiments. In this example embodiment, the PCM switch 300c is configured to have the heating element 310 and the heat spreader 318 on the same side (i.e., the lower side) of the phase change material element 306. Thus, as shown by the arrows 320, heat may flow from the heating element 310 both toward the phase change material element 306 and toward the heat spreader 318. The PCM switch 300c may have different performance characteristics relative to the PCM switch 300a depending on the relative heat capacities of the heating element 310 and the phase change material element 306.

For example, the PCM switch 300c may perform differently than the PCM switch 300a of FIGS. 3A and 3B in that heat may be drawn away from the heating element 310 and the phase change material element 306 (e.g., downward in FIG. 3C) leading to an inefficiency of heating the phase change material element 306. The embodiment of FIG. 3B may perform such that the phase change material element 306 may be directly quenched (i.e., heat removed) after a switching event leading to a faster switching time and more efficient heating of the phase change material element 306 (relative to embodiments in which the heat spreader 318 may be placed on the same side as the heating element 310). However, in embodiments in which the heat capacity of the heating element 310 is significantly greater than that of the phase change material element 306, the heat spreader 318 may be placed next to the heating element 310, as shown in FIG. 3C, so that heat may be rapidly drawn away from the heating element 310 after a switching event.

FIGS. 3D and 3E are vertical cross-sectional views of further PCM switches (300d, 300e), according to various embodiments. In contrast to the embodiments of FIGS. 3A to 3C, the heating element 310 may include the heater pad 314 formed directly in contact with the phase change material element 306 (i.e., without the capping layer 316). Further, as shown respectively in FIGS. 3D and 3E, the heating element 310 may be formed on the same side or on the opposite side of the phase change material element 306 as the heat spreader 318. As described with reference to FIG. 3C, above, one or the other of the PCM switches (300d, 300e) may exhibit better performance depending on the relative heat capacities of the various components of the PCM switches (300d, 300e).

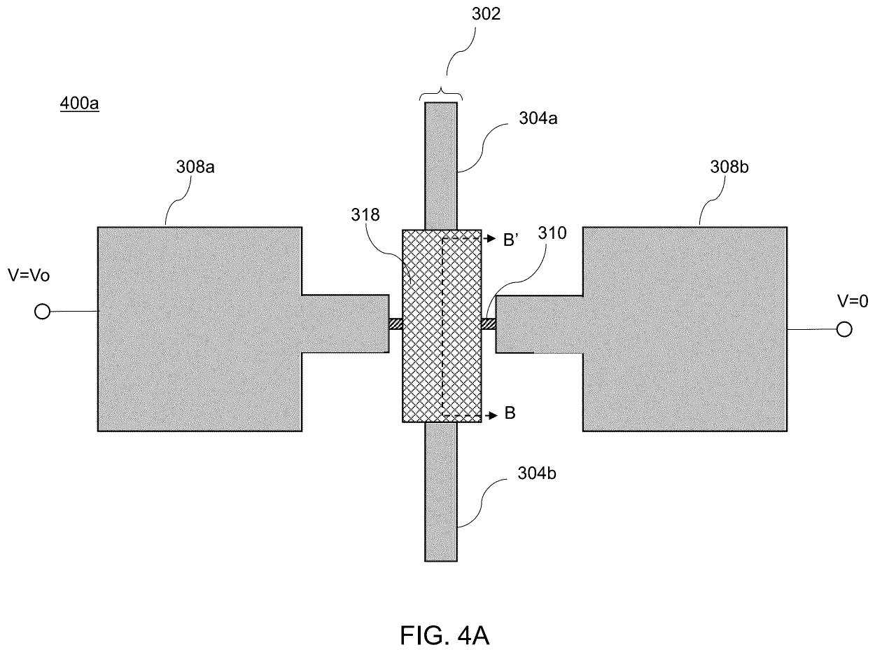

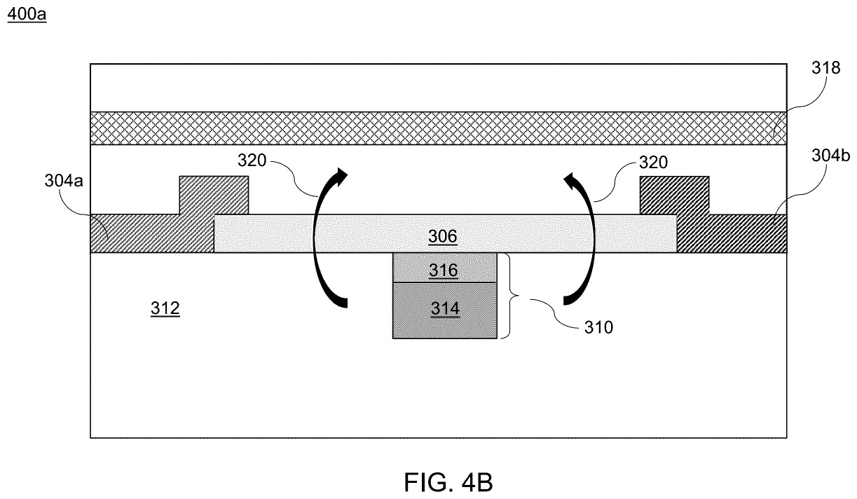

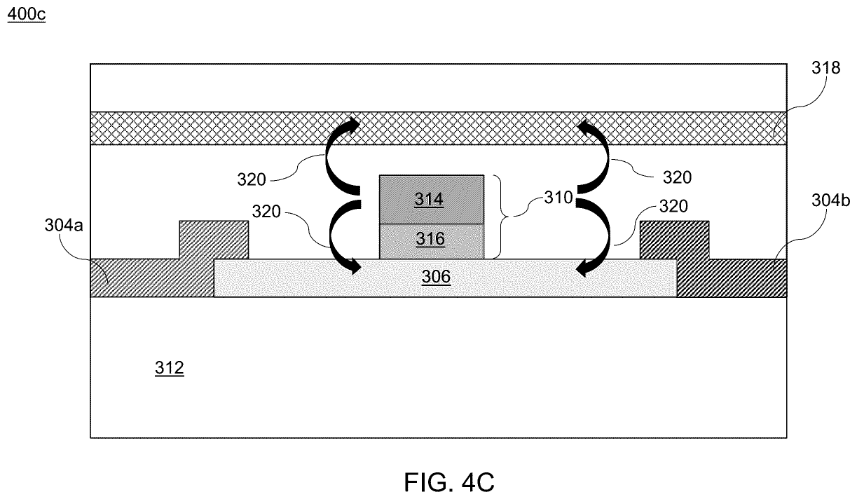

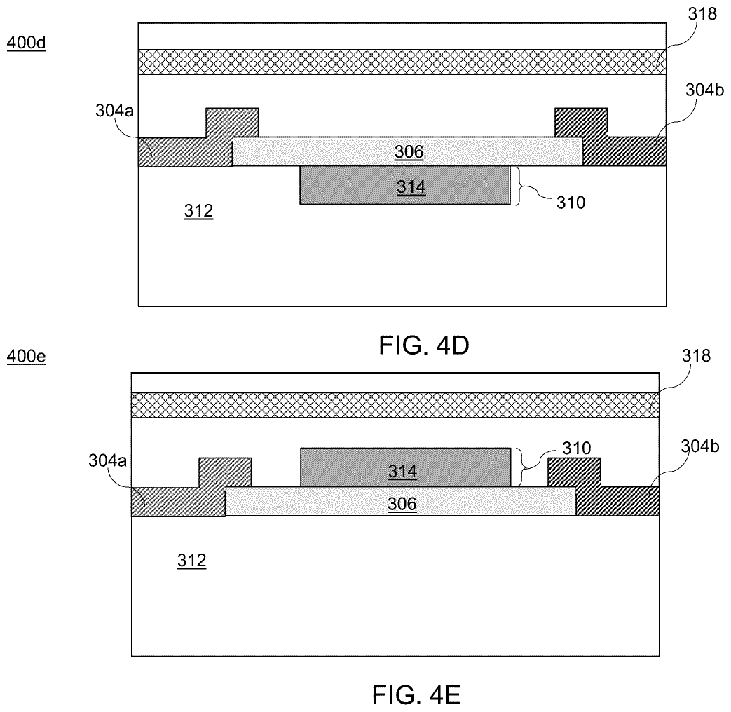

FIG. 4A is a top view of a further PCM switch 400a, and FIG. 4B is a vertical cross-sectional view of a portion of the PCM switch 400a of FIG. 4A, according to various embodiments. The vertical cross-sectional plane that defines the view of FIG. 4B is indicated by the cross-section B-B′ in FIG. 4A. The PCM switch 400a may have many of the same or similar components as those of the PCM switch 300a. In contrast to the embodiment PCM switch 300a of FIGS. 3A and 3B, however, the PCM switch 400a of FIG. 4A may include a configuration in which the position of the heating element 310 and the heat spreader 318 are swapped (e.g., heat spreader 318 above and heating element 310 below the phase change material element 306). As such, heat may preferentially flow from the heating element 310, through the phase change material element 306, and toward the heat spreader 318 in the opposite direction (e.g., up) from that of the embodiment of FIG. 3B, as shown by the arrows 320 in FIG. 4B. Thus, the heating element 310 may be coupled to a first side (e.g., the bottom side) of the phase change material element 306 and the heat spreader 318 may be formed on a second side (e.g., the top side) of the phase change material element 306 opposite to the heating element 310.

As shown in FIGS. 3B and 4B, the heating element 310 may have a localized spatial extent relative to the phase change material element 306. As such, heat may be applied to the phase change material element 306 in a localized distribution. The localized spatial distribution of heat provided to the phase change material element 306 may reduce a power required to switch the phase change material. Further, the presence of the heat spreader 318 may provide more efficient removal of heat following switching events, which may increase a switching speed of the PCM switch.

In some embodiments, the heat spreader 318 may include a metal or a compound semiconductor having a thermal conductivity greater than 100 W/mK. The heat spreader 318 may also include Cu or SiC. The heat spreader 318 may further be electrically isolated from the heating element 310 and the phase change material element 306 (e.g., see FIG. 4B). The heat spreader 318 may further be separated from the phase change material element 306 by an electrically insulating material (e.g., first switch dielectric material layer 312) having a thermal conductivity in a range from approximately 0.1 W/mK to approximately 50 W/mK.

Further, the phase change material element 306 may include a material having a thermal conductivity in a range from approximately 2.5 W/mK to approximately 10 W/mK. The phase change material element 306 may include at least one of a germanium telluride compound, an antimony telluride compound, a germanium antimony telluride compound, a germanium antimony compound, an indium germanium telluride compound, an aluminum selenium telluride compound, an indium selenium telluride compound, and an aluminum indium selenium telluride compound.

The heating element 310 may include a heater pad 314 that generates heat when an applied voltage generates a current through the heater pad 314. The heater pad 314 may further include a material that is at least one of tungsten, tungsten nitride, titanium nitride, and a nickel silicide. Other suitable materials are within the contemplated scope of disclosure. Further, the heater pad 314 may include a material having a thermal conductivity greater than 175 W/mK.

The PCM switches (300a, 300c, 400a, 400c) may further include a dielectric capping layer 316 that is in contact with the phase change material element 306 and that separates the heater pad 314 from the phase change material element 306. The dielectric capping layer 316 may include an electrical insulator having a thermal conductivity greater than 100 W/mK. The dielectric capping layer 316 may include at least one of silicon nitride, silicon carbide, silicon carbide nitride, and aluminum nitride. In some embodiments, the phase change material element 306 may be configured to switch from the conducting phase to the insulating phase within a time that is approximately 5.0×10⁻⁷ sec or less.

The first electrical conductor 304a, the second electrical conductor 304b, and the phase change material element 306 may be configured to form an RF switch (300a, 300c, 400a, 400c) that may block RF signals when the phase change material element 306 is the electrically insulating phase and may conduct RF signals when the when the phase change material element 306 is in the electrically conducting phase. The heat spreader 318 may be formed on a second side of the phase change material element 306 opposite to the heating element 310 (e.g., see FIG. 4B). In certain embodiments, the heat spreader 318 may include a metal or a compound semiconductor having a thermal conductivity greater than 100 W/mK. Further, heat spreader 318 may be electrically isolated from the heating element 310 and the phase change material element 306.

FIG. 4C is a vertical cross sectional view of a further PCM switch 400c, according to various embodiments. In this example embodiment, the PCM switch 400c may be configured to have the heating element 310 and the heat spreader 318 on the same side (i.e., the upper side) of the phase change material element 306. Thus, as shown by the arrows 320, heat may flow from the heating element 310 both toward the phase change material element 306 and toward the heat spreader 318. The PCM switch 400c may have different performance characteristics relative to the PCM switch 400a depending on the relative heat capacities of the heating element 310 and the phase change material element 306.

For example, the PCM switch 400c may exhibit different performance characteristics relative to the PCM switch 400a of FIGS. 4A and 4B in that heat may be drawn away from the heating element 310 and the phase change material element 306 (e.g., upward in FIG. 4C) leading to an inefficiency of heating the phase change material element 306. The embodiment of FIG. 4B may perform such that that the phase change material element 306 may be directly quenched (i.e., heat removed) after a switching event leading to a faster switching time and more efficient heating of the phase change material element 306 (relative to embodiments in which the heat spreader 318 may be placed on the same side as the heating element 310). However, in embodiments in which the heat capacity of the heating element 310 is significantly greater than that of the phase change material element 306, the heat spreader 318 may be placed next to the heating element 310, as shown in FIG. 4C, so that heat may be rapidly drawn away from the heating element 310 after a switching event.

FIGS. 4D and 4E are vertical cross-sectional views of further PCM switches (400d, 400e), according to various embodiments. In contrast to the embodiments of FIGS. 4A to 4C, the heating element 310 may include the heater pad 314 formed directly in contact with the phase change material element 306 (i.e., without the capping layer 316). Further, as shown respectively in FIGS. 4D and 4E, the heating element 310 may be formed on the same side or on the opposite side of the phase change material element 306 as the heat spreader 318. As described with reference to FIG. 4C, above, one or the other of the PCM switches (400d, 400e) may exhibit better performance depending on the relative heat capacities of the various components of the PCM switches (400d, 400e). Various interconnect structures of a semiconductor structure may serve as the heat spreader 318, as described in greater detail, below.

As described above, each of the embodiment PCM switches (300d, 300e, 400d, 400e) of FIGS. 3D, 3E, 4D, and 4E may be configured to have the heater pad 314 formed directly in contact with the phase change material element 306. In contrast, the PCM switches (300a, 300c, 400a, 400c) of FIGS. 3A to 3C and 4A to 4C include a capping layer 316 that separates the heater pad 314 from the phase change material element 306. The PCM switches (300d, 300e, 400d, 400e), that have a direct heating configuration, may exhibit more efficient heat transfer from the heater pad 314 to the phase change material element 306 and may therefore require less power to accomplish a switching event.

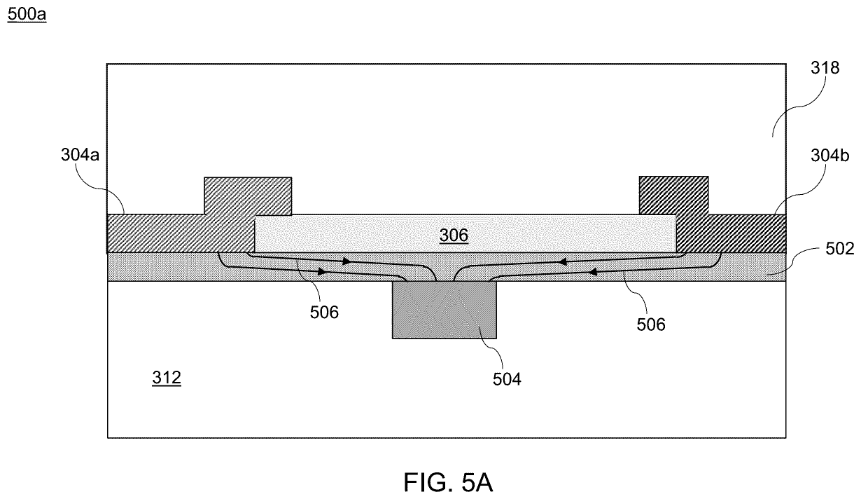

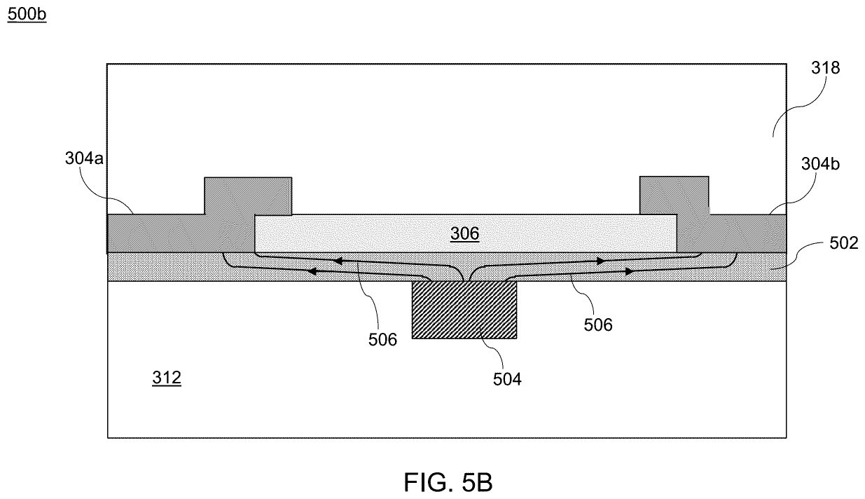

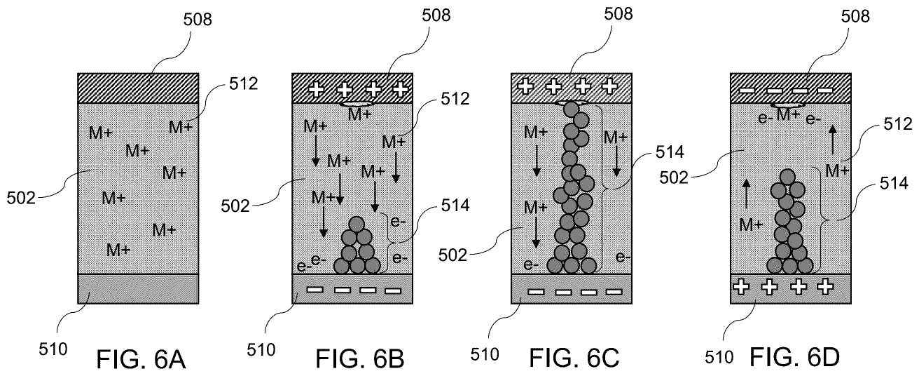

The PCM switches (300d, 300e, 400d, 400e), however, may suffer from material segregation in which components from the heating pad 314 and the phase change material element 306 may mix and form various precipitates due to the direct contact between the heating pad 314 and the phase change material element 306. Such segregation may degrade the material properties of the phase change material element 306, which may degrade the performance of the PCM switches (300d, 300e, 400d, 400e). Thus, embodiments that have an indirect heating configuration, such as PCM switches (300a, 300c, 400a, 400c) of FIGS. 3A to 3C and 4A to 4C may require higher switching power but may exhibit better performance and endurance relative to the PCM switches (300d, 300e, 400d, 400e). As such, the various embodiment switches described above with reference to FIGS. 3A to 4E represent tradeoffs between switching power and performance. The various embodiment PCM switches, described below with reference to FIGS. 5A to 6F may mitigate some or all of the drawbacks of the PCM switches described above with reference to FIGS. 3A to 4E, as follows.

FIG. 5A is a vertical cross-sectional view of a first PCM switch 500a and FIG. 5B is a vertical cross-sectional view of a second PCM switch 500b that each include a direct heating mechanism provided by an ionic resistance change material, according to various embodiments. Each of the first PCM switch 500a and the second PCM switch 500b include a phase change material element 306 electrically coupled to a first electrical conductor 304a and a second electrical conductor 304b. In contrast to the PCM switches described above with reference to FIGS. 3A to 4E, however, each of the first PCM switch 500a and the second PCM switch 500b may include a solid electrolyte 502 (e.g., an example ionic resistance change material) disposed between the phase change material element 306 and a switching electrode 504.

In contrast to the embodiment PCM switches of FIGS. 3A to 4E, the switching electrode 504 is not configured to generate heat. Rather, the switching electrode 504 may be a material that has low resistance and may be configured to apply a potential difference (i.e., voltage) across the solid electrolyte 502. In response to the applied potential difference, metallic ions 506 may flow within the solid electrolyte 502 (e.g., see FIGS. 5A and 5B). The flow of metallic ions 506 may cause metal filaments 514 to form within in the electrolyte 502 (e.g., see FIGS. 6B to 6D) thereby changing the electrical conductivity of the electrolyte.

Current flowing along the metal filaments 514 may generate heat due to Ohmic losses. The current may be geometrically constrained by metal filaments 514 and so the current density may be significantly greater than current density flowing through the switching electrode 504, first electrical conductor 304a, and the second electrical conductor 304b. As such, the metal filaments 514 may act as local heat sources. In this way, the embodiment first PCM switch 500a and the embodiment second PCM switch 500b may exhibit relatively high efficiency of thermal energy transfer due to the close proximity of the heat sources to the phase change material element 306. Further, the first PCM switch 500a and the second PCM switch 500b may be less prone to segregation issues by choosing the solid electrolyte 502 to be a material that is compatible with the phase change material element 306 (i.e., does not cause material segregation). In this way, the first PCM switch 500a and the second PCM switch 500b may not be subject to the tradeoffs between switching power and performance (i.e., endurance) that are characteristics of the embodiments of FIGS. 3A to 4E.

In the embodiment first PCM switch 500a and the second PCM switch 500b shown in FIGS. 5A and 5B, respectively, ionic flow occurs only within the solid electrolyte 502. In both the first PCM switch 500a, and the second PCM switch 500b, heat may be generated within the solid electrolyte 502, which may then be directly transferred to the phase change material element 306. The detailed electrochemical processes governing heat generation in the first PCM switch 500a and the second PCM switch 500b are described in greater detail with reference to FIGS. 6A to 6D, below.

FIGS. 6A to 6D are vertical cross-sectional views of an electrochemical cell including an ionic resistance change material (e.g., solid electrolyte 502) in respective configurations, according to various embodiments. The cell includes the solid electrolyte 502 disposed between an anode 508 and a cathode 510. The anode 508 may be configured to be an oxidizable (i.e., ionizable) electrode, such as Ag, Cu, Al, etc., while the cathode 510 may be a relatively inert electrode, such as Pt, Ir, Au, W, TiN, etc. The solid electrolyte 502 may be chosen to allow transport of positively charged ions (i.e., cations) of the metal corresponding to that of the anode 508. FIG. 6A illustrates the electrochemical cell in a first configuration in which there is no potential difference (i.e., voltage or electrochemical potential) between the anode 508 and the cathode 510. As shown, the solid electrolyte 502 may include a plurality of metal cations 512 and may support ionic conduction. In the example embodiment of FIGS. 5A and 6A to 6D, the solid electrolyte 502 may be chosen to have good ionic conductivity but poor charge conductivity.

As shown, in FIG. 6B, application of a positive voltage on the anode 508 and a negative voltage on the cathode 510 may cause partial dissolution of the anode which thereby generates metal cations 512 according to the oxidation reaction M_{(anode)}>M^{z+}+ze− (where z is an integer). The metal cations 512 may enter the solid electrolyte 502 and flow toward the cathode 510. The electrons ze− liberated by the oxidation reaction may be transferred from the anode 508 to the cathode 510 through an external circuit (not shown). The metal cations 512 flowing through solid electrolyte 502 may combine with electrons provided by the cathode 510 to form a metal filament 514 according to the reduction reaction M^{z+}+ze−→M (filament).

As shown in FIG. 6C, if the voltage difference between the anode 508 and the cathode 510 is maintained for a sufficient time, the metal filament 514 may extend from the cathode 510 to the anode 508 thereby generating a direct electrically conductive pathway between the cathode 510 and the anode 508. When this occurs, the conductivity of the electrochemical cell may increase significantly. An electrical current may then flow along the metal filament 514 and may generate heat due to Ohmic loss, as mentioned above.

As shown in FIG. 6D, the chemical reactions that gave rise to the metal filament 514 may be reversed by reversing the polarity of the applied voltage. In this regard, the voltage applied to the anode 508 may be changed from a positive voltage to a negative voltage, and the voltage applied to the cathode 510 may be changed from a negative voltage to a positive voltage, as shown in FIG. 6D. The metal atoms of the metal filament 514 may then be oxidized according to the oxidation reaction M^{(filament)}→M^{z+}+ze− (where z is an integer) and the liberated electrons ze− may flow from the cathode 510 to the anode 508 through an external circuit (not shown). Similarly, the metal cations 512 generated by the oxidation reaction may flow through the solid electrolyte 502 to the anode 508.

The metal cations 512 arriving at the anode 508 may then be re-incorporated into the anode 508 through the reduction reaction M^{z+}+ze−→M_{(anode)} in which metal cations 512 arriving at the anode 508 from the solid electrolyte 502 may be combined with electrons ze− provided by the anode 508. In this way, the metal filament 514 may be dissolved and the conductivity of the electrochemical cell may return to its high resistive state (e.g., the state illustrated in FIG. 6A). As such, the solid electrolyte 502 may be configured as an ionic resistance change material having a resistance that may be reversibly switched from a high value to a low value through application of a first voltage difference (e.g., see FIGS. 6B and 6C) and a second voltage difference (e.g., see FIG. 6D), respectively, and vice versa.

The embodiment first PCM switch 500a of FIG. 5A may have a configuration similar to that of FIGS. 6A to 6D in which metallic ions 506 (e.g., metal cations 512) may flow along a direct path from an anode 508 (e.g., the first electrical conductor 304a and the second electrical conductor 304b) to a cathode 510 (e.g., the switching electrode 504). Alternatively, as shown in FIG. 5B, the second PCM switch 500b may be configured such that the metal ions 506 may flow along a direct path from an anode 508 (e.g., the switching electrode 504) to a cathode 510 (e.g., the first electrical conductor 304a and the second electrical conductor 304b).

A wide assortment of oxides, higher chalcogenides (compounds of S, Se, Te), halides, and other insulating materials may be used to form the solid electrolyte 502. These compounds generally fall into three categories; (ion) electrolytes, such as AgI and related materials and Ag-polymers; mixed (ion-electron) conductors such as Ag_{2+δ}S, Cu_{2-δ}S, Cu_{2-δ}O, Ag—AsSₓ, Ag−GeSeₓ, Cu−GeSeₓ, Ag−GeSₓ, Cu−GeSₓ, Cu−GeTe, Cu-TCNQ, and a-Si; and insulators that are not ordinarily considered as solid electrolytes such as SiO₂, Al₂O₃, WO₃, Ta₂O₅, TiO₂, GeOₓ, ZrO₂, HfO₂, graphene oxide, Si₃N₄, AlN, and MSQ, typically combined with Cu or Ag or a Cu/Ag-containing material. Various forms of carbon, including carbon nanotubes, graphene-like conductive carbon, and insulating carbon may also be used to form the solid electrolyte 502.

The various materials of the anode 508, solid electrolyte 502, and cathode 510 may be formed by various deposition techniques including evaporation, RF sputtering, electron beam deposition, physical vapor deposition (PVD), radio-frequency physics vapor deposition (RF-PVD), chemical vapor deposition (CVD), plasma-enhanced chemical vapor deposition (PECVD), atomic layer deposition (ALD), etc. Example systems may include (anode/electrolyte/cathode) Ag/Ag₃₃Ge₂₀Se₄₇/Ni, Ag/Ag—GeSe/Pt, Al/Cu/Ge_{0.5}Se_{0.5}/W, Ag or Cu/GeS/W, Ag/Sb:GeS₂/W, Cu/Ta₂O₅/Pt, Cu/Ta₂O₅/W, Cu/Cu:SiO₂/W, Ag/a-Si/SiGe/W, Ag/Si₃N₄/Pt, Cu/Cu—Te/GdOₓ/W, Cu/Ta/TaSiO_{y}/Ru, Al/Cu/Ti/TaOₓ/W, Cu—Te/Al₂O₃/Si, Al/TiN/Cu/TiW/Al₂O₃/W, etc. As shown in these examples, certain components of the anode/electrolyte/cathode structure may include multi-layer structures. For example, Al/Cu/Ge_{0.5}Se_{0.5}/W include a multi-layer anode 508 including layers of Al and Cu, while Ag/a-Si/SiGe/W include a multi-layer solid electrolyte 502 including layers of a-Si and SiGe.

Metal-doped chalcogenide glasses provide an example of how ions (e.g., metal cations 512) may move in the solid electrolyte 502. In these materials, the metal ions (M+) may be associated with non-bridging chalcogens (Ch−) but the M-Ch bonds may be quite long (e.g., around 0.25 nm in Ag—Ge—S ternaries). The coulombic energy is inversely proportional to the (fixed) anion-(mobile) cation 512 separation and so these long bonds result in small attractive forces, <0.5 eV (assuming a dielectric constant in excess of 10 which is reasonable for these materials), making it relatively easy to dislocate the metal cations 512. Between these sites there may exist a potential barrier with an activation energy that includes this coulombic energy and a strain energy term. The strain component may arise from the structure of the supporting material which impedes the motion of the migrating ions. In general, ternary chalcogenide glasses may be more flexible than a typical oxide glass and this effect may reduce the strain energy component.

The strain energy term may give rise to different ion mobility in ostensibly equivalent compositions for films deposited under different conditions; for example, thermally evaporated films are more “relaxed” and open than films made by methods such as atomic layer deposition (ALD) and so the latter tend to have lower ion mobility and generally poorer switching characteristics. Device programming history may also influence the openness of the pathways and possibly reduce the strain energy term. Ion mobility generally is a function of both terms and, put simply, the materials with the highest mobility will be those which have the lowest coulombic energy and the most “open” physical pathways through the material for the ions, leading to the lowest strain component. The activation energy for this combined barrier typically ranges from around 0.2 eV to 0.6 eV for the ion conductors mentioned above.

To form the solid electrolyte 502, several percent to several tens of atomic percent (at. %) of the mobile metal may be added to the base glasses to form the solid electrolyte 502. If the metal mostly reacts with the chalcogen in the base glass to form M-Ch, which is likely in the case of Ag and Cu in Ch-rich materials, almost all of the metal can be mobile. The metal can be incorporated in the source material or during fabrication of the device layers. In particular, Ag may be added to a chalcogenide base glass film via the process of photodissolution. This process may involve light energy greater than the optical gap of the glass to create charged defects at the interface between a thin layer of the metal and the chalcogenide. The holes so created may be trapped by the metal to form ions while the electrons diffuse into the chalcogenide film.

The resulting electric field may be sufficient to allow the ions to overcome the energy barrier at the interface and move into the chalcogenide. This may lead to the formation of an interfacial monolayer of a Ag+ rich phase (e.g., in Ag-rich materials) which supplies the metal ions deep into the film, driven by drift and diffusion. The light used for photodissolution is typically the same as that used for photolithography (i.e., a wavelength of 365 nm). This corresponds to an energy of 3.39 eV, which is more than sufficient to ionize chalcogenide glasses which typically have an optical gap less than 3 eV. Oxides tend to have much larger gaps (SiO2 is in the order of 9 eV) and so thermal diffusion of metal is favored over photodissolution.

The switching time for a given system (anode 508, solid electrolyte 502, cathode 510) generally depends on the strength of the applied switching electric field, as determined by the applied voltage difference between the anode 508 and the cathode 510. For example, in a system with an Ag anode 508 and a solid electrolyte 502 containing Ag₂S, the switching time may vary from 1 sec to one microsecond as function of the applied voltage in a range from 0.05 V to 0.35 V. Similar behavior may be found in a system having a Cu anode 508 with a solid electrolyte 502 containing Cu₂S. In this regard, the switching time for this system may be in a range from 1 sec to one microsecond as the switching voltage is varied from 0.1 V to 0.4 V.

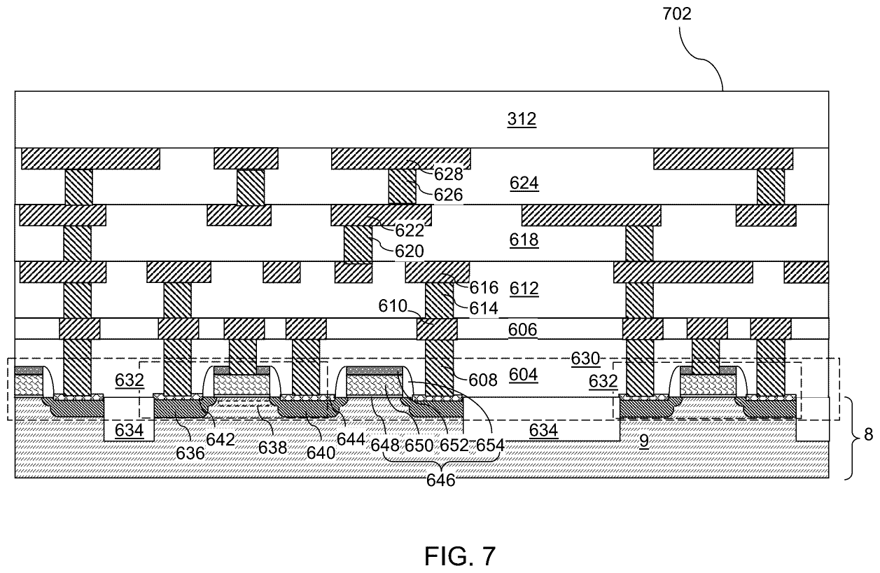

FIG. 7 is a vertical cross-sectional view of a first exemplary structure prior to formation of a PCM switch according to various embodiments. The first exemplary structure may include a substrate 8, which may be a semiconductor substrate such as a commercially available silicon substrate. The substrate 8 may include a semiconductor material layer 9 at least at an upper portion thereof. The semiconductor material layer 9 may be a surface portion of a bulk semiconductor substrate or may be a top semiconductor layer of a semiconductor-on-insulator (SOI) substrate. In one embodiment, the semiconductor material layer 9 may include a single crystalline semiconductor material such as single crystalline silicon. In one embodiment, the substrate 8 may include a single crystalline silicon substrate including a single crystalline silicon material.

Shallow trench isolation structures 634 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 634. Field effect transistors 632 may be formed over the top surface of the semiconductor material layer 9. For example, each field effect transistor 632 may include a source electrode 636, a drain electrode 640, a semiconductor channel 638 that may include a surface portion of the substrate 8 extending between the source electrode 636 and the drain electrode 640, and a gate structure 646. The semiconductor channel 638 may include a single crystalline semiconductor material.

Each gate structure 646 may include a gate dielectric layer 648, a gate electrode 650, a gate cap dielectric 652, and a dielectric gate spacer 654. A source-side metal-semiconductor alloy region 642 may be formed on each source electrode 636, and a drain-side metal-semiconductor alloy region 644 may be formed on each drain electrode 640. The devices formed on the top surface of the semiconductor material layer 9 may include complementary metal-oxide-semiconductor (CMOS) transistors and optionally additional semiconductor devices (such as resistors, diodes, capacitor structures, etc.), and are collectively referred to as CMOS circuitry 630.

One or more of the field effect transistors 632 in the CMOS circuitry 630 may include a semiconductor channel 638 that contains a portion of the semiconductor material layer 9 in the substrate 8. If the semiconductor material layer 9 may include a single crystalline semiconductor material such as single crystalline silicon, the semiconductor channel 638 of each field effect transistor 632 in the CMOS circuitry 630 may include a single crystalline semiconductor channel such as a single crystalline silicon channel. In one embodiment, a subset of the field effect transistors 632 in the CMOS circuitry 630 may include a respective node that is subsequently electrically connected to a node of a PCM switch to be subsequently formed.

In one embodiment, the substrate 8 may include a single crystalline silicon substrate, and the field effect transistors 632 may include a respective portion of the single crystalline silicon substrate as a semiconducting channel. As used herein, a “semiconducting” element refers to an element having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein and is capable of producing a doped material having electrical conductivity in a range from 1.0 S/cm to 1.0×10⁵ S/cm upon suitable doping with an electrical dopant.

Various metal interconnect structures formed within dielectric material layers may be subsequently formed over the substrate 8 and the semiconductor devices 632 thereupon (such as field effect transistors). In an illustrative example, the dielectric material layers may include, for example, a first dielectric material layer 604 that may be a layer that surrounds the contact structure connected to the source and drains (sometimes referred to as a contact-level dielectric material layer 604), a first interconnect-level dielectric material layer 606, a second interconnect-level dielectric material layer 612, a third interconnect-level dielectric material layer 618, and a fourth interconnect-level dielectric material layer 624.

The metal interconnect structures may include device contact via structures 608 formed in the first dielectric material layer 604 and contact a respective component of the CMOS circuitry 630, first metal line structures 610 formed in the first interconnect-level dielectric material layer 606, first metal via structures 614 formed in a lower portion of the second interconnect-level dielectric material layer 612, second metal line structures 616 formed in an upper portion of the second interconnect-level dielectric material layer 612, second metal via structures 620 formed in a lower portion of the third interconnect-level dielectric material layer 618, third metal line structures 622 formed in an upper portion of the third interconnect-level dielectric material layer 618, third metal via structures 626 formed in a lower portion of the fourth interconnect-level dielectric material layer 624, and fourth metal line structures 628 formed in an upper portion of the fourth interconnect-level dielectric material layer 624. While this disclosure is described using an embodiment in which four levels of metal line structures are formed in dielectric material layers, embodiments are expressly contemplated herein in which a lesser or greater number of levels of metal line structures are formed in dielectric material layers.

Each of the dielectric material layers (604, 606, 612, 618, 624) may include a dielectric material such as undoped silicate glass, a doped silicate glass, organosilicate glass, amorphous fluorinated carbon, porous variants thereof, or combinations thereof. Each of the metal interconnect structures (608, 610, 614, 616, 620, 622, 626, 628) may include at least one conductive material, which may be a combination of a metallic liner (such as a metallic nitride or a metallic carbide) and a metallic fill material. Each metallic liner may include TIN, TaN, WN, TiC, TaC, and WC, and each metallic fill material portion may include W, Cu, Al, Co, Ru, Mo, Ta, Ti, alloys thereof, and/or combinations thereof. Other suitable metallic liner and metallic fill materials within the contemplated scope of disclosure may also be used. In one embodiment, the first metal via structures 614 and the second metal line structures 616 may be formed as integrated line and via structures by a dual damascene process. Generally, any contiguous set of a metal line structure (616, 622, 628) and at least one underlying metal via structure (614, 620, 626) may be formed as an integrated line and via structure.

Generally, semiconductor devices 632 may be formed on a substrate 8, and metal interconnect structures (608, 610, 614, 616, 620, 622, 626, 628) and dielectric material layers (604, 606, 612, 618, 624) over the semiconductor devices 632. The metal interconnect structures (608, 610, 614, 616, 620, 622, 626, 628) may be formed in the dielectric material layers (604, 606, 612, 618, 624), and may be electrically connected to the semiconductor devices.

Referring again to FIG. 7, a first switch dielectric material layer 312 may be formed over the metal interconnect structures (608, 610, 614, 616, 620, 622, 626, 628) and dielectric material layers (604, 606, 612, 618, 624). The first switch dielectric material layer 312 may include a suitable dielectric material, such as silicon oxide, undoped silicate glass, a doped silicate glass, organosilicate glass, amorphous fluorinated carbon, porous variants thereof, or combinations thereof. Other suitable dielectric materials are within the contemplated scope of disclosure. The first switch dielectric material layer 312 may be deposited using any suitable deposition process, such a chemical vapor deposition (CVD), physical vapor deposition (PVD), atomic layer deposition (ALD), high density plasma CVD (HDPCVD), metalorganic CVD (MOCVD), plasma enhanced CVD (PECVD), sputtering, laser ablation, or the like. The first switch dielectric material layer 312 may include a planar upper surface 702.

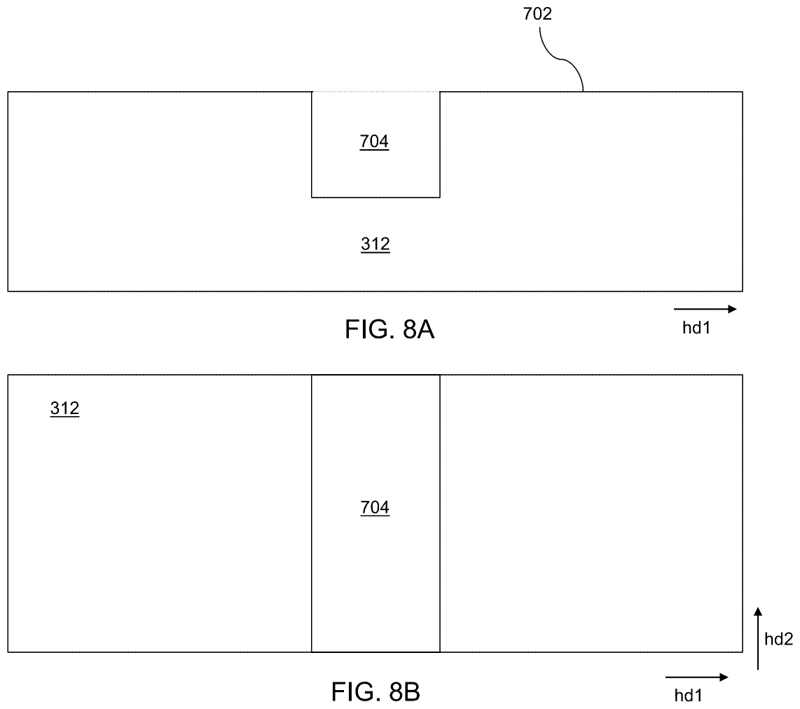

FIG. 8A is a vertical cross-section view of an exemplary intermediate structure during a process of forming a PCM switch illustrating a trench 704 formed in the first switch dielectric material layer 312, according to various embodiments. FIG. 8B is a top view of the exemplary intermediate structure of FIG. 8A. A patterned photoresist or hard mask (not shown) may be formed over a top surface of the first switch dielectric material layer 312. An anisotropic etch process, such as a reactive ion etch process, may then be performed to etch a portion of the dielectric material layer 312 exposed through an opening in the patterned photoresist or hard mask. As shown in FIGS. 8A and 8B, the trench 704 may have a rectangular cross-sectional shape in a plane extending along second horizontal direction hd2, including a horizontal bottom surface and vertically-extending sidewalls. However, it will be understood that the trench 704 may have a different cross-sectional shape, such as a trapezoidal cross-section shape, and the sidewalls of the trench may include angled or curved surfaces. Following the etching process, the patterned photoresist or hard mask may be removed using a suitable process, such as via ashing or dissolution using a solvent.

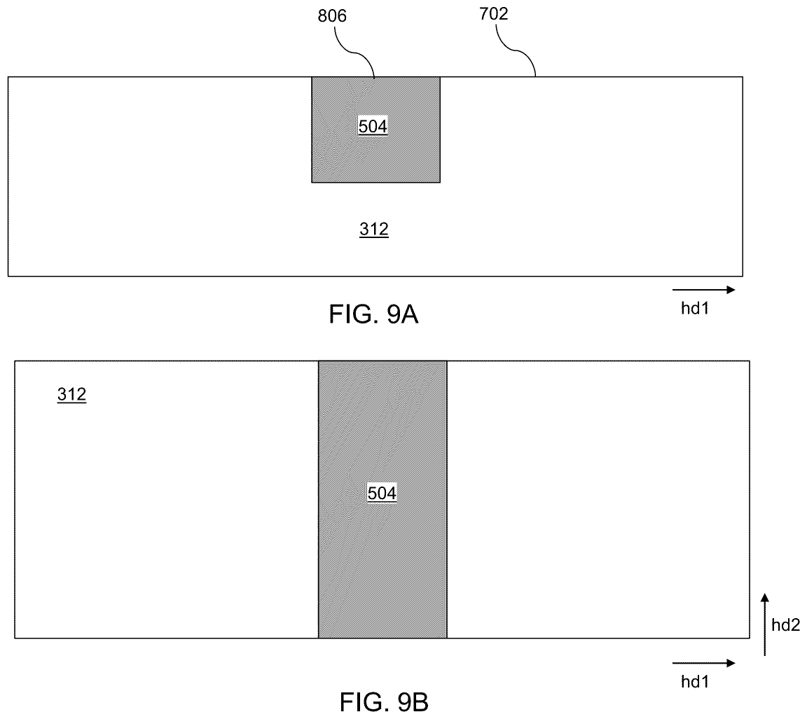

FIG. 9A is a vertical cross-section view of an exemplary intermediate structure during a process of forming a PCM switch illustrating a switching electrode 504 embedded within the first switch dielectric material layer 312, according to various embodiments. FIG. 9B is a top view of the exemplary intermediate structure of FIG. 9A. The exemplary intermediate structure of FIGS. 9A and 9B may be formed from the exemplary intermediate structure of FIGS. 8A and 8B by depositing a conductive material into the trench 704 in the first switch dielectric material layer 312 to form the switching electrode 504. The conductive material deposited into the trench 704 to form the switching electrode 504 may include a metallic liner material and a metallic fill material. The metallic liner material may include a conductive metallic nitride or a conductive metallic carbide such as TIN, TiN/W, Ti/Al/Ti, TaN, WN, TiC, TaC, and/or WC. The metallic fill material may include W, Cu, Al, Ag, Co, Ru, Mo, Ta, Ti, alloys thereof, and/or combinations thereof. Other suitable metallic liner and metallic fill materials within the contemplated scope of this disclosure may also be used.

The metallic liner material and metallic fill materials may be formed by suitable deposition process, which may include one or more of a CVD process, a PVD process, an ALD process, an electroplating process, etc. Other suitable deposition processes are within the contemplated scope of disclosure. Excess portions of the conductive material may be removed from over the upper surface 702 of the first switch dielectric material layer 312 by a planarization process so that the upper surface 806 of the switching electrode 504 and the upper surface 702 of the first switch dielectric material layer 312 are substantially co-planar. The planarization process may include use of a CMP process although other suitable planarization processes may be used. The first switch dielectric material layer 312 may surround the switching electrode 504 over the bottom surface and lateral side surfaces of the switching electrode 504, as shown in FIG. 9A.

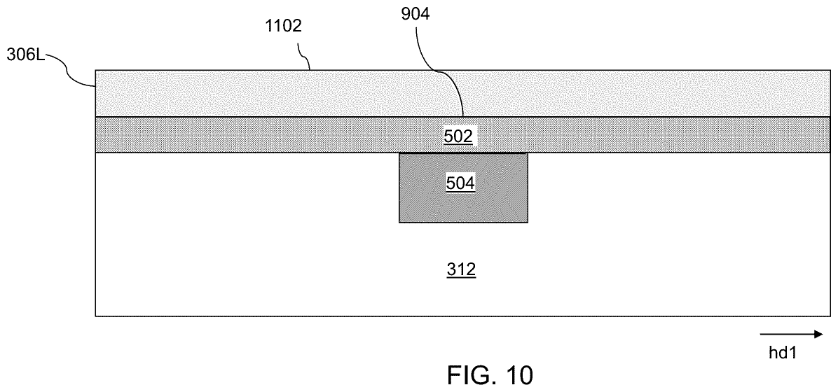

FIG. 10 is a vertical cross-section view of an exemplary intermediate structure during a process of forming a PCM switch showing a continuous phase change material (PCM) layer 306L formed over an upper surface 904 of a solid electrolyte 502, according to various embodiments. The solid electrolyte 502 may be deposited by evaporation, RF sputtering, electron beam deposition, physical vapor deposition (PVD), radio-frequency physics vapor deposition (RF-PVD), chemical vapor deposition (CVD), plasma-enhanced chemical vapor deposition (PECVD), atomic layer deposition (ALD), etc. Example materials may include one or more of AgI, an Ag-polymer, Ag_{2+δ}S, Cu_{2-δ}S, Cu_{2-δ}O, Ag—AsSₓ, Ag—GeSeₓ, Cu—GeSeₓ, Ag—GeSₓ, Cu—GeSₓ, Cu—GeTe, Cu-TCNQ, a-Si, SiO₂, Al₂O₃, WO₃, Ta₂O₅, TiO₂, GeOₓ, ZrO₂, HfO₂, graphene oxide, Si₃N₄, AlN, and MSQ, combined with Cu or Ag or a Cu/Ag-containing material.

The continuous PCM layer 306L may be deposited over the upper surface 904 of the solid electrolyte 502 using a suitable deposition process as described above. The continuous PCM layer 306L may include a suitable phase change material having at least two distinct phases providing different resistivity, such as a high resistivity amorphous phase and a low resistivity crystalline phase. Suitable phase change materials for the continuous PCM layer 306L may include, without limitation, germanium telluride compounds, antimony telluride compounds, germanium antimony telluride (GST) compounds such as Ge₂Sb₂Te₅ or GeSb₂Te₄, germanium antimony compounds, indium germanium telluride compounds, aluminum selenium telluride compounds, indium selenium telluride compounds, and/or aluminum indium selenium telluride compounds. In some embodiments, the phase change material may be doped using a suitable dopant, such as indium or antimony, or the phase change material may be undoped. Other suitable materials for the continuous PCM layer 306L are within the contemplated scope of disclosure.

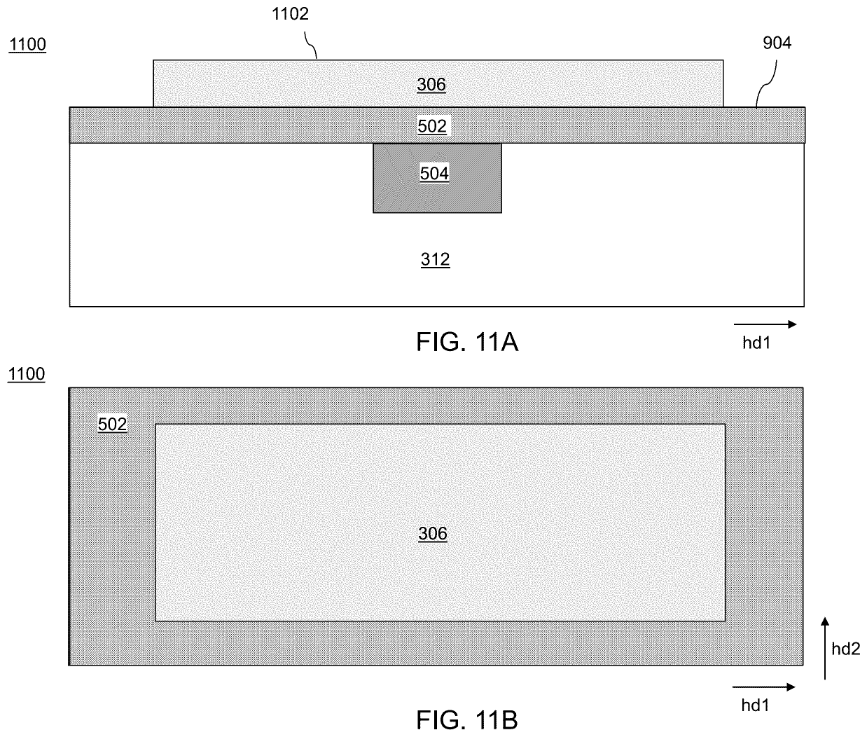

FIG. 11A is a vertical cross-section view of an exemplary intermediate structure during a process of forming a PCM switch illustrating a discrete phase change material element 306 over the upper surface 904 of the solid electrolyte 502, according to various embodiments. FIG. 11B is a top view of the exemplary intermediate structure of FIG. 11A. The phase change material element 306 may be formed by performing an etching process, such as an anisotropic etching process, to remove portions of the continuous PCM layer 306L of FIG. 10. In this regard, a patterned mask (not shown) may be formed by depositing a layer of photoresist over the upper surface 1102 of the continuous PCM layer 306L, and lithographically patterning the photoresist to provide the patterned mask.

The patterned mask may cover a portion of the continuous PCM layer 306L overlying the solid electrolyte 502. The portion of the patterned mask overlying the solid electrolyte 502 may have a greater lateral dimension along a first horizontal direction hd1 than the solid electrolyte 502 and the switching electrode 504 along a first horizontal direction hd1 and may have a lesser lateral dimension than the solid electrolyte 502 along a second horizontal direction hd2 that is perpendicular to the first horizontal direction hd1.

The etching process may expose the upper surface 904 of the solid electrolyte 502 surrounding the phase change material element 306. In various embodiments, the phase change material element 306 may have a greater lateral dimension along the first horizontal direction hd1 than the solid electrolyte 502 and the switching electrode 504 and may have a lesser lateral dimension than the solid electrolyte 502 and the switching electrode 504 along the second horizontal direction hd2 (e.g., see FIGS. 11A and 10B). Following the etching process, the patterned mask may be removed using a suitable process, such as via ashing or dissolution using a solvent.

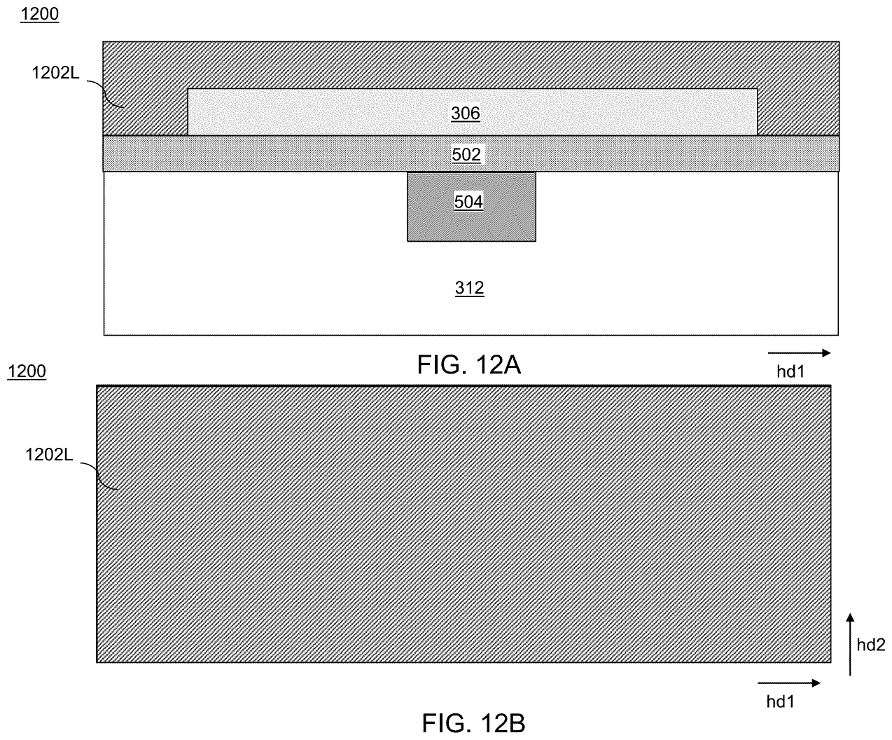

FIG. 12A is a vertical cross-section view of an exemplary intermediate structure 1200 during a process of forming a PCM switch, and FIG. 12B is a top view of the exemplary intermediate structure 1200 of FIG. 12A, according to various embodiments. The exemplary intermediate structure of FIGS. 12A and 12B may be formed from the exemplary intermediate structure of FIGS. 11A and 11B by depositing a continuous electrode layer 1202L over the intermediate structure 1100 of FIGS. 11A and 11B. The continuous electrode layer 1202L may be formed by depositing an electrically conductive material over the exposed upper surfaces of the solid electrolyte 502 and over the upper surface and side surfaces of the phase change material element 306. The continuous electrode layer may include a metallic material having relatively low electrical resistivity, such as tungsten, tungsten nitride, nickel silicide, and/or aluminum. Other suitable materials for the continuous electrode layer are within the contemplated scope of disclosure. The continuous electrode layer may be deposited using a suitable deposition process as described above.

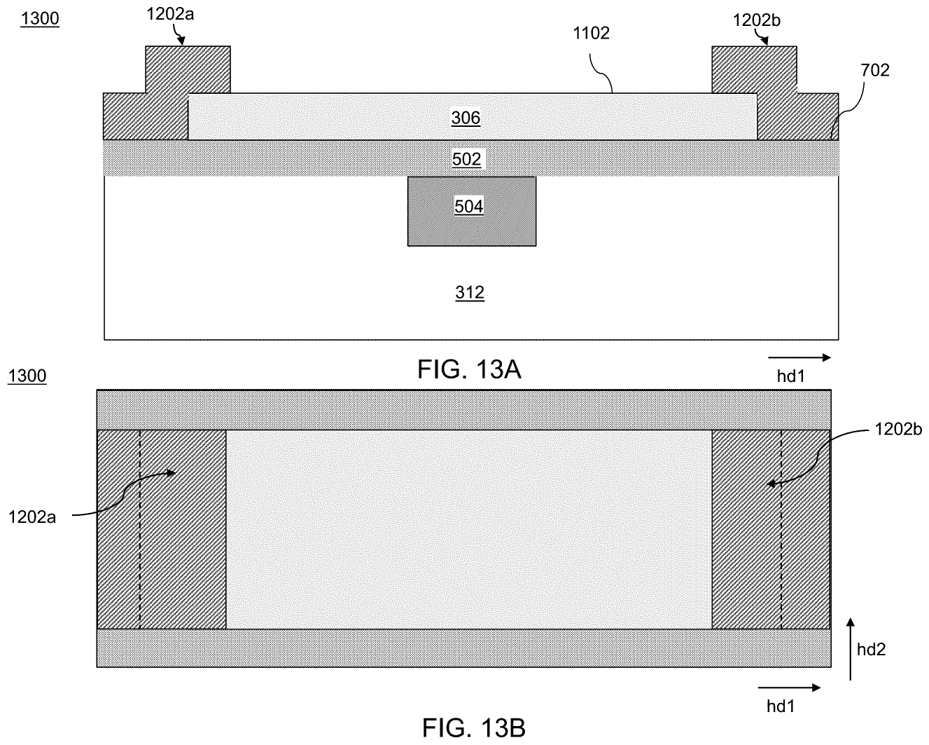

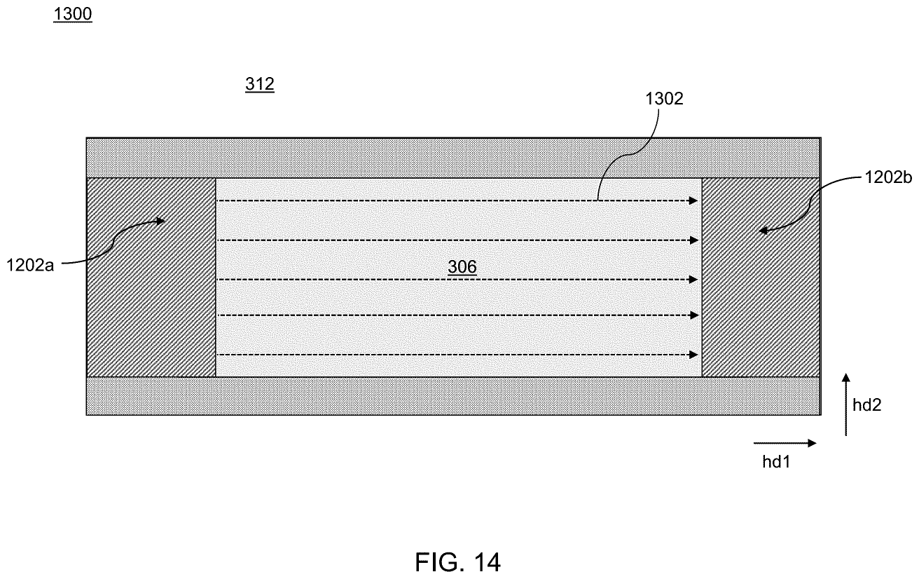

FIG. 13A is a vertical cross-section view of a PCM switch 1300 including a first electrode 1202a and a second electrode 1202b formed over the upper surface 904 of the solid electrolyte 502 and the upper surface 1102 and side surfaces of the phase change material element 306. FIG. 13B is a top view of the PCM switch 1300 of FIG. 13A. The PCM switch 1300 may be formed by etching the continuous electrode layer 1202L of FIGS. 12A and 12B to form the first electrode 1202a and a second electrode 1202b. In this regard, patterned mask (not shown) may be formed over the continuous electrode layer 1202L by depositing a layer of photoresist over the continuous electrode layer, and lithographically patterning the photoresist to provide the patterned mask. The patterned mask may expose a region of the continuous electrode layer 1202L that overlies the switching electrode 504 and the solid electrolyte 502 and may cover portions of the continuous electrode layer 1202L that overlie peripheral regions of the phase change material element 306 on opposite sides of the phase change material element 306.

An etching process, such as an anisotropic etching process, may then be performed to remove portions of the continuous electrode layer 1202L that are exposed through the patterned mask and to generate discrete the first electrode 1202a and the second electrode 1202b over the upper surface upper surface 1102 and side surfaces of the phase change material element 306. The etching process may expose a portion of the upper surface 1102 of the phase change material element 306 between the first electrode 1202a and the second electrode 1202b, as shown in FIG. 13A. In various embodiments, the first electrode 1202a and the second electrode 1202b may be electrically connected to the first electrical conductor 304a and the second RF conductor, respectively (e.g., see FIGS. 3A and 4A).

As described above with reference to FIGS. 5A to 6D, the properties of the ionic resistance change material (i.e., the solid electrolyte 502) may be changed by application of voltage differences between the switching electrode 504, the first electrode 1202a, and the second electrode 1202b. In the example embodiment first PCM switch 500a of FIG. 5A, the first electrode (304a, 1202a) and the second electrode (304b, 1202b) may include an oxidizable metal (e.g., Ag, Cu, etc.) and the switching electrode 504 may include an inert metal (e.g., Pt, Ir, Au, W, TiN, etc.). Application of a positive voltage to the first electrode (304a, 1202a) and the second electrode (304b, 1202b) and a negative voltage to the switching electrode 504, may cause metal filaments 514 (e.g., see FIGS. 6B, 6C and 6D) to form in the solid electrolyte 502. Current flowing along the metal filaments 514 may generate heat due to Ohmic loss. Such heat may be directly transferred to the phase change material element 306 to change a conductive state of the phase change material element 306.

In the example embodiment 500b of FIG. 5B, the first electrode (304a, 1202a) and the second electrode (304b, 1202b) may include an inert metal (e.g., Pt, Ir, Au, W, TiN, etc.) and the switching electrode 504 may include an oxidizable metal (e.g., Ag, Cu, etc.). Application of a negative voltage to the first electrode (304a, 1202a) and the second electrode (304b, 1202b) and a positive voltage to the switching electrode 504, may cause metal filaments 514 (e.g., see FIGS. 6B, 6C and 6D) to form in the phase change material element (e.g., within the solid electrolyte 502 in FIGS. 6B to 6D). As such, heat may be generated directly in the phase change material element 306 due to Ohmic loss. Such heat may change a conductive state of the phase change material element 306.

By controlling the time dependent characteristics of the voltage applied to the switching electrode 504, the first electrode (304a, 1202a), and the second electrode (304b, 1202b), a thermal profile within a portion of the phase change material element 306 overlying the switching electrode 504 may be controlled. For example, a voltage pulse having a relatively short pulse width and rapid pulse falling time may quickly heat a portion of the phase change material element 306 above its melting temperature (Tₘₑₗₜ), causing the phase change material element 306 to transition from a low-resistivity state to a high-resistivity state, while the rapid falling time of the current pulse may cause the portion of the phase change material element 306 to rapidly quench and avoid recrystallization as it cools. Thus, the phase change material element 306 may retain its high resistivity state indefinitely following the application of the current pulse.

In contrast, a voltage pulse having a relatively longer pulse width and longer falling time may heat a portion of the phase change material element 306 to a temperature above its crystallization temperature (T_{crys}), but below its melting temperature (Tₘₑₗₜ), causing the phase change material element 306 to undergo crystal nucleation, while the long falling time of the voltage pulse may promote crystal growth in the phase change material element 306 as it gradually cools, thereby causing the phase change material element 306 to transition from a high-resistivity state to a low-resistivity state. The phase change material element 306 may retain this low resistivity state indefinitely until the application of a subsequent current pulse that is configured to transition the phase change material element 306 to a high-resistivity state.

In some embodiments, the first heater pad 308a and the second heater pad 308b (e.g., see FIGS. 3A and 4A) that may be connected to the switching electrode 504 (e.g., see FIGS. 5A and 5B) may be electrically coupled to control circuitry configured to selectively control the application of voltage pulses through the switching electrode 504 and the first electrode (304a, 1202a) and the second electrode (304b, 1202b) to thereby control (i.e., program) the resistance state of the phase change material element 306. For example, one or both of first heater pad 308a and the second heater pad 308b may be coupled to one or more transistors 632 via metal interconnect structures (608, 610, 614, 616, 620, 622, 626, 628) as shown in FIG. 7.

FIG. 14 is a top view of a PCM switch 1300 schematically illustrating a signal pathway across the PCM switch 1300 according to various embodiments. In this regard, an input signal, such as a radiofrequency (RF) signal, may be transmitted to the first electrode 1202a from the first electrical conductor 304a (e.g., see FIGS. 3A and 4A). In instances in which the phase change material element 306 is in a low-resistivity state, the PCM switch 1300 is “On,” (i.e., the PCM switch is closed) and the signal may be transmitted across the phase change material element 306 to the second electrode 1202b and to the second electrical conductor 304b (e.g., see FIGS. 3A and 4A), as schematically indicated by arrows 1302. In instances in which the phase change material element 306 is in a high-resistivity state, the PCM switch 1300 is “Off” (i.e., the PCM switch is open) and the signal transmission to the second electrode 1202b and to the second electrical conductor 304b may be blocked.

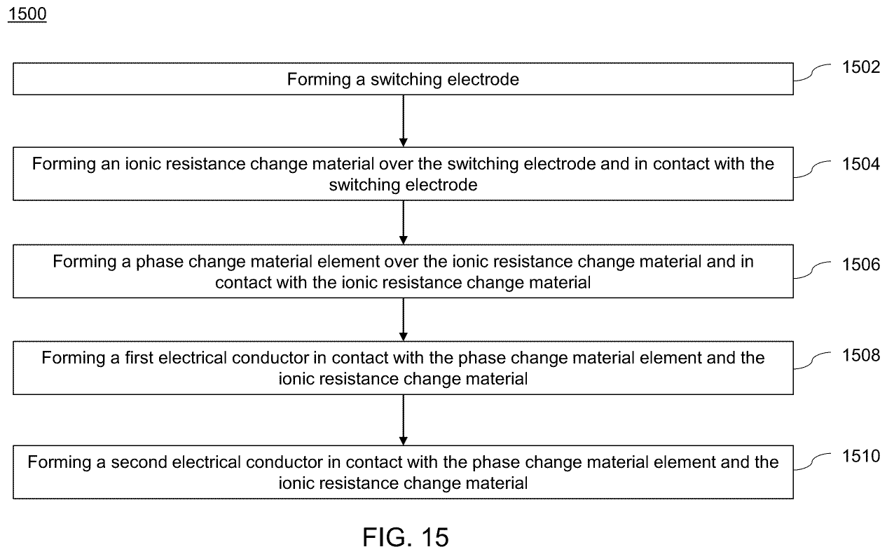

FIG. 15 is a flowchart illustrating operations of an embodiment method 1500 of fabricating a PCM switch (500a, 500b), according to various embodiments. In operation 1502, the method 1500 may include forming a switching electrode 504. In operation 1504, the method 1500 may include forming an ionic resistance change material (e.g., solid electrolyte 502) over the switching electrode 504 and in contact with the switching electrode 504. In operation 1506, the method 1500 may include forming a phase change material element 306 over the ionic resistance change material 502 and in contact with the ionic resistance change material 502. In operation 1508, the method 1500 may include forming a first electrical conductor (e.g., first electrical conductor 304a) in contact with the phase change material element 306 and the ionic resistance change material 502. In operation 1510, the method 1500 may include forming a second electrical conductor (e.g., second electrical conductor 304b) in contact with the phase change material element 306 and the ionic resistance change material 502.

The method 1500 may further include forming the first electrical conductor 304a, the second electrical conductor 304b, and the phase change material element 306 to be configured as an RF switch that is switchable from an electrically insulating phase that blocks RF signals to an electrically conducting phase that conducts RF signals. The method 1500 may further include forming the switching electrode 504 to include an inert metal and forming the first electrical conductor 304a and the second electrical conductor 304b to each include an oxidizable metal. In other embodiments, the method 1500 may include forming the switching electrode 504 to include an oxidizable metal and forming the first electrical conductor 304a and the second electrical conductor 304b to each an inert metal.

Referring to all drawings and according to various embodiments of the present disclosure, a PCM switch (500a, 500b) is provided. The PCM switch (500a, 500b) may include a phase change material element 306 including a first electrode (e.g., first electrical conductor 304a) and a second electrode (e.g., second electrical conductor 304b), and a direct heating element including an ionic resistance change material (e.g., solid electrolyte 502) contacting the phase change material element 306. The PCM switch (500a, 500b) may further include a switching electrode 504 contacting the ionic resistance change material 502 such that the ionic resistance change material 502 is disposed between the phase change material element 306 and the switching electrode 504.

In certain embodiments, the first electrode 304a and the second electrode 304b may include an oxidizable metal and the switching electrode 504 may include an inert metal. The ionic resistance change material 502 may have a high resistance state and a low resistance state and the ionic resistance change material may be configured to switch from the high resistance state to the low resistance state in response to a positive voltage applied to the first electrode 304a and the second electrode 304b and a negative voltage applied to the switching electrode 504. In this example embodiment (e.g., see FIG. 5A), the ionic resistance change material 502 may include conducting metal filaments 514 in the low resistance state and may include dissolved metal ions 512 in the high resistance state.

In various embodiments, the ionic resistance change material 502 may be configured to generate heat within the ionic resistance change material 502 due to Ohmic loss in the low resistance state and to transfer the heat to the phase change material element 306 through direct contact between the ionic resistance change material 502 and the phase change material element 306. In other embodiments, the first electrode 304a and the second electrode 304b may include an inert metal and the switching electrode 504 may include an oxidizable metal. The ionic resistance change material 502 may include have a high resistance state and a low resistance state. The ionic resistance change material 502 may be configured to switch from the high resistance state to the low resistance state in response to a negative voltage applied to first electrode 304a and the second electrode 304b and a positive voltage applied to the switching electrode 504.

In this example embodiment (e.g., see FIG. 5B), the ionic resistance change material 502 may include conducting metal filaments 514 in the low resistance state and may include dissolved metal ions 512 in the high resistance state (e.g., see FIGS. 6A to 6D). The ionic resistance change material 502 may be configured to generate heat within the ionic resistance change material 502 due to Ohmic loss in the low resistance state and to transfer the heat to the phase change material element 306 through direct contact between the ionic resistance change material 502 and the phase change material element 306.

The phase change material element 306 may include at least one of a germanium telluride compound, an antimony telluride compound, a germanium antimony telluride compound, a germanium antimony compound, an indium germanium telluride compound, an aluminum selenium telluride compound, an indium selenium telluride compound, and an aluminum indium selenium telluride compound. The ionic resistance change material 502 may include one or more of AgI, an Ag-polymer, Ag_{2+δ}S, Cu_{2-δ}S, Cu_{2-δ}O, Ag—AsSₓ, Ag—GeSeₓ, Cu—GeSeₓ, Ag—GeSₓ, Cu—GeSₓ, Cu—GeTe, Cu-TCNQ, a-Si, SiO₂, Al₂O₃, WO₃, Ta₂O₅, TiO₂, GeOₓ, ZrO₂, HfO₂, graphene oxide, Si₃N₄, AlN, and MSQ, combined with Cu or Ag or a Cu/Ag-containing material. In various embodiments, the phase change material element 306 may include a material having a thermal conductivity in a range from approximately 2.5 W/mK to approximately 10 W/mK. Further, the phase change material element 306 may be configured to switch from an electrically conducting phase to an electrically insulating phase within a time that is approximately 5.0×10⁻⁷ sec or less.

In other example embodiments of the present disclosure, a PCM switch (500a, 500b) is provided. The PCM switch (500a, 500b) may include a phase change material element 306, a first electrical conductor 304a coupled the phase change material element 306, a second electrical conductor 304b coupled to the phase change material element 306, a direct heating element including an ionic resistance change material 502 contacting the phase change material element 306 and configured to supply a heat pulse to the phase change material element 306, and a switching electrode 504 contacting the ionic resistance change material 502 such that the ionic resistance change material 502 is disposed between the phase change material element 306 and the switching electrode 504. The ionic resistance change material 502 may include a high resistance state and a low resistance state. Further, the first electrical conductor 304a, the second electrical conductor 304b, and the phase change material element 306, may be configured to form an RF switch that is switchable from an electrically insulating phase that blocks RF signals to an electrically conducting phase that conducts RF signals.

In certain embodiments, the first electrode 304a and the second electrode 304b may include an oxidizable metal and the switching electrode 504 may include an inert metal. Electrical currents passing through the ionic resistance change material 502 in the low resistance state may generate heat within the ionic resistance change material 502 due to Ohmic loss, and the generated heat may be transferred to the phase change material element 306 through direct contact with the ionic resistance change material 502. In other embodiments, the first electrode 304a and the second electrode 304b may include an inert metal and the switching electrode 504 may include an oxidizable metal. Electrical currents flowing through the ionic resistance change material 502 in the low resistance state may generate heat within the ionic resistance change material 502 due to Ohmic loss and the heat may be transferred to the phase change material element 306 through direct contact with the ionic resistance change material 502.

Disclosed embodiment PCM switches may be desired as they may include a direct heat source that does not lead to problems with material segregation. In this regard, an ionic resistance change material 502 (i.e., a solid electrolyte) may be formed in direct contact with a phase change material element 306. In a low resistive state, the ionic resistance change material 502 may form electrically conducting filaments 514 that may support electrical currents having a relatively high current density that may act as local heat sources. In this way, the embodiment PCM switches may exhibit relatively high efficiency of thermal energy transfer due to the close proximity of the heat sources to the phase change material element.

Further, the embodiment PCM switches may be less prone to segregation issues by incorporating a solid electrolyte that is compatible with the phase change material element, thus leading to greater endurance relative to existing PCM switches having direct contact heat sources. In this regard, embodiment PCM switches may exhibit endurance (i.e., durability) that is comparable to or greater than that of existing PCM switches having indirect heat sources (and consequently require higher switching power). As such, the embodiment PCM switches may not be subject to tradeoffs between switching power and performance (i.e., endurance) that are characteristics of existing PCM switches.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A phase change material (PCM) switch, comprising:
a phase change material element comprising a first electrode and a second electrode; and
a direct heating element comprising an ionic resistance change material contacting the phase change material element.

2. The PCM switch of claim 1, further comprising a switching electrode contacting the ionic resistance change material such that the ionic resistance change material is disposed between the phase change material element and the switching electrode.

3. The PCM switch of claim 2, wherein the first electrode and the second electrode comprise an oxidizable metal and the switching electrode comprises an inert metal.

4. The PCM switch of claim 3, wherein:
the ionic resistance change material comprises a high resistance state and a low resistance state, and
the ionic resistance change material is configured to switch from the high resistance state to the low resistance state in response to a positive voltage applied to the first electrode and the second electrode and a negative voltage applied to the switching electrode.

5. The PCM switch of claim 4, wherein the ionic resistance change material comprises conducting metal filaments in the low resistance state, and
wherein the ionic resistance change material comprises dissolved metal ions in the high resistance state.

6. The PCM switch of claim 5, wherein the ionic resistance change material is configured:
to generate heat within the ionic resistance change material due to Ohmic loss in the low resistance state; and
to transfer the heat to the phase change material element through direct contact between the ionic resistance change material and the phase change material element.

7. The PCM switch of claim 2, wherein the first electrode and the second electrode comprise an inert metal and the switching electrode comprises an oxidizable metal.

8. The PCM switch of claim 7, wherein:
the ionic resistance change material comprises a high resistance state and a low resistance state, and
the ionic resistance change material is configured to switch from the high resistance state to the low resistance state in response to a negative voltage applied to the first electrode and the second electrode and a positive voltage applied to the switching electrode.

9. The PCM switch of claim 8, wherein the ionic resistance change material comprises conducting metal filaments in the low resistance state, and
wherein the ionic resistance change material comprises dissolved metal ions in the high resistance state.

10. The PCM switch of claim 9, wherein the ionic resistance change material is configured:
to generate heat within the ionic resistance change material due to Ohmic loss in the low resistance state; and
to transfer the heat to the phase change material element through direct contact between the ionic resistance change material and the phase change material element.

11. The PCM switch of claim 1, wherein the phase change material element comprises at least one of a germanium telluride compound, an antimony telluride compound, a germanium antimony telluride compound, a germanium antimony compound, an indium germanium telluride compound, an aluminum selenium telluride compound, an indium selenium telluride compound, or an aluminum indium selenium telluride compound.

12. The PCM switch of claim 1, wherein the ionic resistance change material comprises one or more of AgI, an Ag-polymer, Ag_{2+δ}S, Cu_{2-δ}S, Cu_{2-δ}O, Ag—AsSₓ, Ag—GeSeₓ, Cu—GeSeₓ, Ag—GeSₓ, Cu—GeSₓ, Cu—GeTe, Cu-TCNQ, a-Si, SiO₂, Al₂O₃, WO₃, Ta₂O₅, TiO₂, GeOₓ, ZrO₂, HfO₂, graphene oxide, Si₃N₄, AlN, and MSQ, combined with Cu or Ag or a Cu/Ag-containing material.

13. The PCM switch of claim 1, wherein the phase change material element comprises a material having a thermal conductivity in a range from approximately 2.5 W/mK to approximately 10 W/mK.

14. The PCM switch of claim 1, wherein the phase change material element is configured to switch from an electrically conducting phase to an electrically insulating phase within a time that is approximately 5.0×10⁻⁷ sec or less.

15. A phase change material (PCM) switch, comprising:
a phase change material element;
a first electrical conductor coupled the phase change material element;
a second electrical conductor coupled to the phase change material element;
a direct heating element comprising an ionic resistance change material contacting the phase change material element and configured to supply a heat pulse to the phase change material element; and
a switching electrode contacting the ionic resistance change material such that the ionic resistance change material is disposed between the phase change material element and the switching electrode,
wherein the ionic resistance change material comprises a high resistance state and a low resistance state, and
wherein the first electrical conductor, the second electrical conductor, and the phase change material element, form an RF switch that is switchable from an electrically insulating phase that blocks RF signals to an electrically conducting phase that conducts RF signals.

16. The PCM switch of claim 15, wherein:
the first electrical conductor and the second electrical conductor comprise an oxidizable metal and the switching electrode comprises an inert metal;
electrical currents passing through the ionic resistance change material in the low resistance state generate heat within the ionic resistance change material due to Ohmic loss; and
the heat is transferred to the phase change material element through direct contact with the ionic resistance change material.

17. The PCM switch of claim 15, wherein:
the first electrical conductor and the second electrical conductor comprise an inert metal and the switching electrode comprises an oxidizable metal, and
electrical currents flowing through the ionic resistance change material in the low resistance state generate heat within the ionic resistance change material due to Ohmic loss; and
the heat is transferred to the phase change material element through direct contact with the ionic resistance change material.

18. A method of forming a PCM switch, comprising:
forming a switching electrode;
forming an ionic resistance change material over the switching electrode and in contact with the switching electrode;
forming a phase change material element over the ionic resistance change material and in contact with the ionic resistance change material;
forming a first electrical conductor in contact with the phase change material element and the ionic resistance change material; and
forming a second electrical conductor in contact with the phase change material element and the ionic resistance change material,
wherein the first electrical conductor, the second electrical conductor, and the phase change material element, form an RF switch that is switchable from an electrically insulating phase that blocks RF signals to an electrically conducting phase that conducts RF signals.

19. The method of claim 18, wherein forming the switching electrode further comprises forming the switching electrode to comprise an inert metal, and
wherein forming the first electrical conductor and the second electrical conductor further comprises forming the first electrical conductor and the second electrical conductor from an oxidizable metal.

20. The method of claim 18, wherein forming the switching electrode further comprises forming the switching electrode to comprise an oxidizable metal, and
wherein forming the first electrical conductor and the second electrical conductor further comprises forming the first electrical conductor and the second electrical conductor from an inert metal.
